(19) United States
(12) Patent Application Publication
(10) Pub. No.: US 2025/0016987 A1
(43) Pub. Date: Jan. 9, 2025

(54) SEMICONDUCTOR MEMORY DEVICE

(71) Applicant: Samsung Electronics Co., Ltd., Suwon-si (KR)

(72) Inventors: Jae Won NA, Suwon-si (KR); Jul Pin PARK, Suwon-si (KR); Jong Moo LEE, Suwon-si (KR); Chang Sik KIM, Suwon-si (KR)

(73) Assignee: Samsung Electronics Co., Ltd., Suwon-si (KR)

(21) Appl. No.: 18/396,289

(22) Filed: Dec. 26, 2023

(30) Foreign Application Priority Data
Jul. 3, 2023 (KR) 10-2023-0085652

(51) Int. Cl. H10B 12/00

(52) U.S. Cl. CPC H10B 12/482; H10B 12/02; H10B 12/315; H10B 12/50

(57) ABSTRACT

A semiconductor memory device including a bit line including a metal and extending in a first direction on a substrate; a channel structure on the bit line, including a first channel pattern extending in a second direction, and a second channel pattern spaced apart from the first channel pattern in the first direction and extending in the second direction; a liner film between the bit line and the channel structure, and including the metal; a first word line between the first and second channel patterns, and the first word line extending in the second direction; a second word line between the first and second channel patterns, and extending in the second direction, and the second word line spaced apart from the first word line in the first direction; and first and second capacitors respectively on the first and second channel patterns, and connected to the first and second channel patterns.

### CROSS-REFERENCE TO RELATED APPLICATION

This application claims priority from Korean Patent Application No. 10-2023-0085652 filed on Jul. 3, 2023 in the Korean Intellectual Property Office under 35 U.S.C. 119, the contents of which in its entirety are herein incorporated by reference.

### BACKGROUND

### 1. Field

The present disclosure relates to semiconductor memory devices, and more particularly to semiconductor memory devices including a vertical channel transistor (VCT).

### 2. Description of the Related Art

There is a need to increase the degree of integration of semiconductor memory devices to satisfy excellent performance and low price required by consumers. In the case of semiconductor memory devices, because the degree of integration is an important factor in determining the price of a product, an increased degree of integration is particularly required.

In the case of a two-dimensional or planar semiconductor memory device, the degree of integration is mainly determined by an area occupied by unit memory cells, and is therefore greatly affected by the level of fine pattern forming technology. However, since ultra-expensive apparatuses are required to miniaturize the patterns, the degree of integration of two-dimensional semiconductor memory devices is increasing, but is still limited. Accordingly, semiconductor memory devices that include a vertical channel transistor having a channel extending in a vertical direction are proposed.

### SUMMARY

Embodiments of the inventive concepts provide a semiconductor memory device having improved degree of integration and electrical characteristics.

However, aspects of the inventive concepts are not restricted as set forth herein. The above and other aspects of the inventive concepts will become more apparent to one of ordinary skill in the art to which the inventive concepts pertain by referencing the detailed description given below.

Embodiments of the inventive concepts provide a semiconductor memory device that includes a bit line including a metal and extending in a first direction on a substrate; a channel structure on the bit line, the channel structure including a first channel pattern extending in a second direction, and the channel structure including a second channel pattern spaced apart from the first channel pattern in the first direction and extending in the second direction; a liner film between the bit line and the channel structure, and the liner film including the metal; a first word line between the first channel pattern and the second channel pattern, and the first word line extending in the second direction; a second word line between the first channel pattern and the second channel pattern, the second word line extending in the second direction, and the second word line spaced apart from the first word line in the first direction; and a first capacitor and a second capacitor respectively on the first channel pattern and the second channel pattern, and connected to the first channel pattern and the second channel pattern.

Embodiments of the inventive concepts further provide a semiconductor memory device that includes a bit line extending on a substrate in a first direction; a protruding insulating pattern on the substrate, the protruding insulating pattern including a channel trench exposing the bit line and the protruding insulating pattern extending in a second direction intersecting the first direction; a liner film on an upper surface of the exposed bit line; a channel structure extending along a lower surface and side surface of the channel trench, and the channel structure including a first channel pattern and a second channel pattern spaced apart from the first channel pattern in the first direction; a first word line and a second word line on the channel structure, and the first word line and the second word line spaced apart from each other in the first direction and each extending in the second direction; a gate insulating film between the first channel pattern and the first word line, and the gate insulating film between the second channel pattern and the second word line; and a first capacitor and a second capacitor respectively on the first channel pattern and the second channel pattern, and the first capacitor and the second capacitor connected to the first channel pattern and the second channel pattern.

Embodiments of the inventive concepts still further provide a semiconductor memory device that includes a peri-gate structure on a substrate; a bit line on the peri-gate structure, and extending in a first direction; a protruding insulating pattern on the substrate, the protruding insulating pattern including a channel trench exposing the bit line and the protruding insulating pattern extending in a second direction intersecting the first direction; a channel structure in the channel trench, and the channel structure including a horizontal part, and a first vertical part and a second vertical part protruding from the horizontal part; a liner film between the bit line and the horizontal part of the channel structure, and the liner film including a nitride; a first word line on the channel structure, and the first word line extending in the second direction; a second word line on the channel structure, the second word line extending in the second direction, and the second word line spaced apart from the first word line in the first direction; a gate insulating film between the first vertical part of the channel structure and the first word line, and between the second vertical part of the channel structure and the second word line; a gate separation pattern on the horizontal part of the channel structure, and the gate separation pattern separating the first word line and the second word line; and a first capacitor and a second capacitor on the channel structure, and the first capacitor and the second capacitor respectively connected to the first vertical part of the channel structure and the second vertical part of the channel structure.

### BRIEF DESCRIPTION OF DRAWINGS

The above and other aspects and features of the present disclosure will become more apparent in view of the following description of example embodiments with reference to the attached drawings, in which:

FIG. 1 is a layout diagram for explaining a semiconductor memory device according to some example embodiments.

FIG. 2 is a cross-sectional view taken along A-A and B—B of FIG. 1.

FIG. 3 is a cross-sectional view taken along C-C and D-D of FIG. 1.

FIG. 4 is an enlarged view of a portion P of FIG. 2.

FIGS. 5, 6, 7 and 8 are enlarged views of a portion Q of FIG. 4, respectively.

FIGS. 9 and 10 are enlarged views of a portion P of FIG. 2.

FIG. 11 is a diagram for explaining a semiconductor memory device according to some example embodiments.

FIG. 12 is a diagram for explaining a semiconductor memory device according to some example embodiments.

FIGS. 13, 14, 15, 16 and 17 are diagrams for explaining a semiconductor memory device according to some example embodiments.

FIGS. 18, 19 and 20 are diagrams for explaining a semiconductor memory device according to some example embodiments.

FIGS. 21, 22, 23 and 24 are diagrams for explaining a semiconductor memory device according to some example embodiments.

FIGS. 25, 26, 27, 28, 29, 30, 31, 32, 33, 34, 35, 36, 37, 38 and 39 are diagrams for explaining a method for fabricating a semiconductor memory device according to some example embodiments.

FIGS. 40, 41, 42, 43, 44 and 45 are diagrams for explaining a method for fabricating a semiconductor memory device according to some example embodiments.

### DETAILED DESCRIPTION OF THE EMBODIMENTS

When used in this specification, the terminology “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

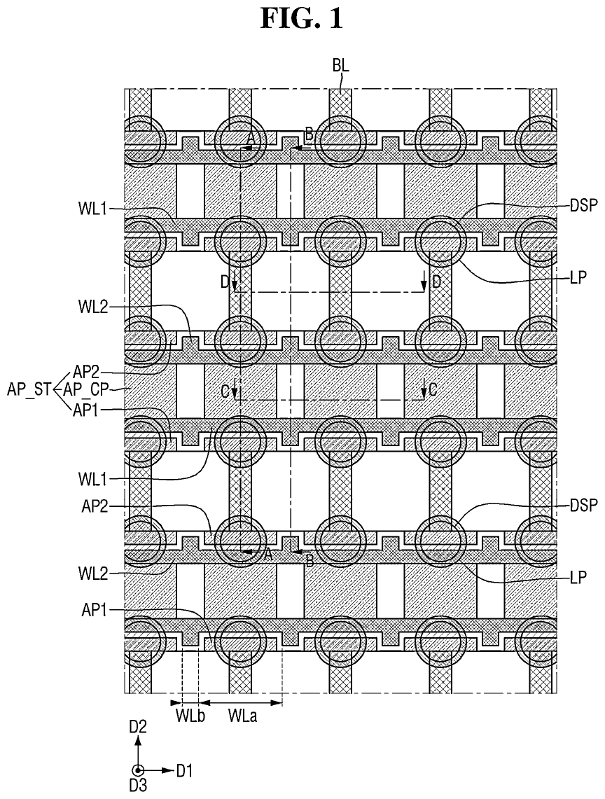

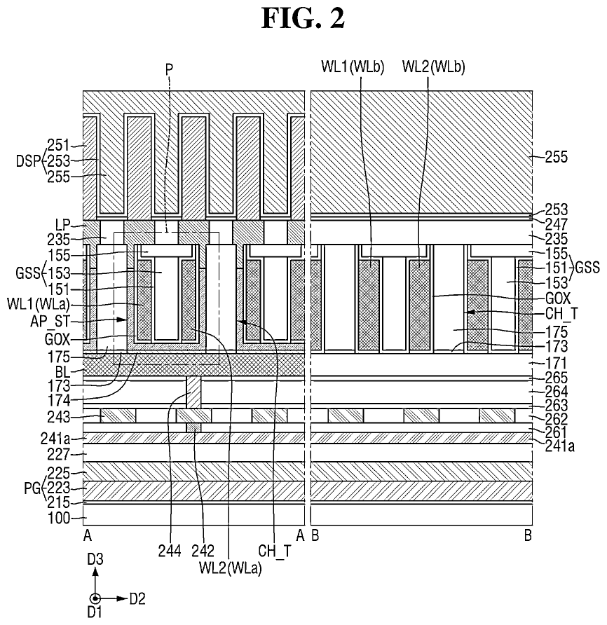

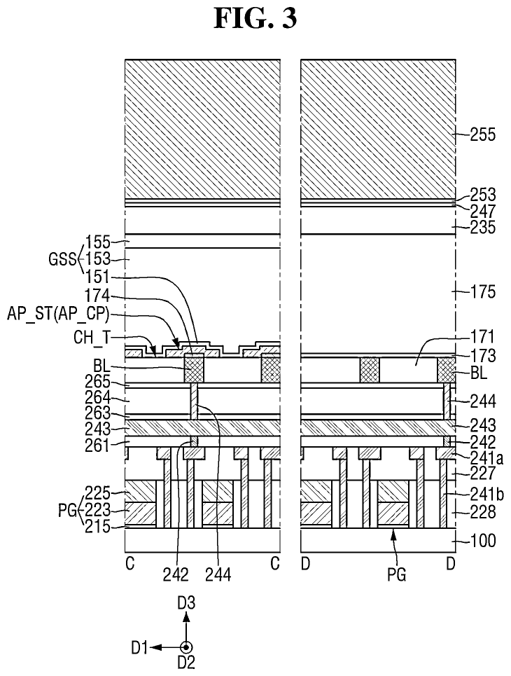

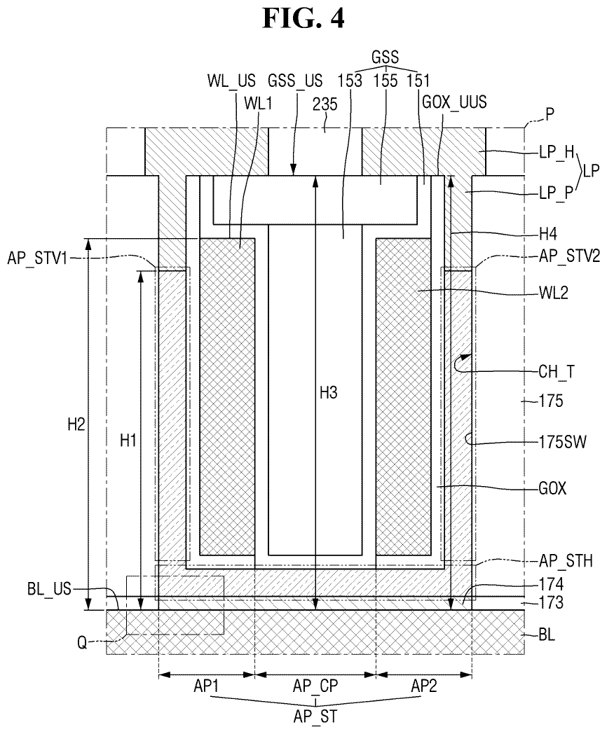

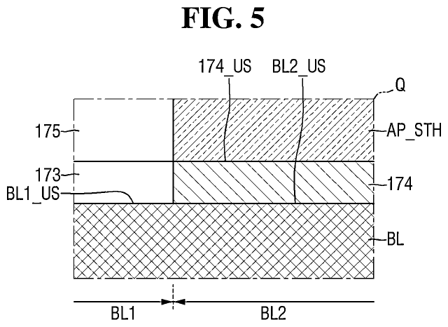

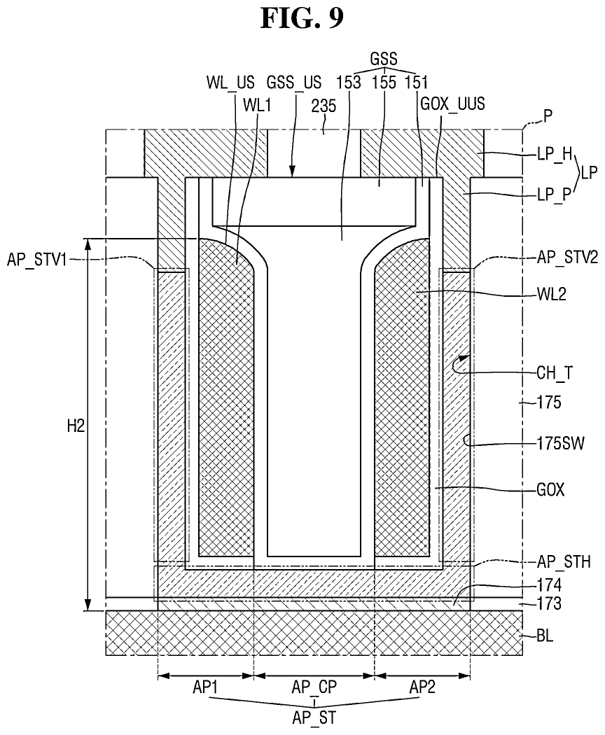

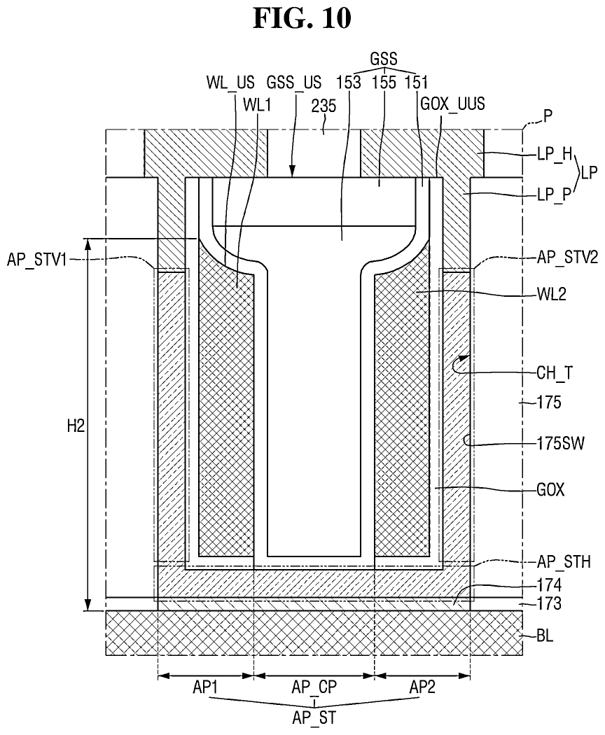

FIG. 1 is a layout diagram for explaining a semiconductor memory device according to some example embodiments. FIG. 2 is a cross-sectional view taken along A-A and B—B of FIG. 1. FIG. 3 is a cross-sectional view taken along C-C and D-D of FIG. 1. FIG. 4 is an enlarged view of a portion P of FIG. 2. FIGS. 5 to 8 are enlarged views of a portion Q of FIG. 4, respectively. FIGS. 9 and 10 are enlarged views of a portion P of FIG. 2.

The semiconductor memory device according to some example embodiments of the inventive concepts may include memory cells including a vertical channel transistor (VCT).

Referring to FIGS. 1 to 12, the semiconductor memory device according to some example embodiments may include a peri-gate structure PG, bit lines BL, word lines WL1 and WL2, channel structures AP_ST, liner films 174, protruding insulating patterns 175, and data storage patterns DSP.

A substrate 100 may be a silicon substrate, or may include other materials, for example, but not limited to, silicon germanium, indium antimonide, lead telluride, indium arsenide, indium phosphide, gallium arsenide or gallium antimonide.

A peri-gate structure PG may be disposed on the substrate 100. The substrate 100 may include a cell array region and a peripheral circuit region. The peri-gate structure PG may be disposed over the cell array region and the peripheral circuit region. In other words, a part of the peri-gate structure PG is disposed in the cell array region of the substrate 100, and the rest of the peri-gate structure PG may be disposed in the peripheral circuit region of the substrate 100.

The peri-gate structure PG may be included in a sensing transistor, a transfer transistor, a driving transistor, and the like. The types of transistors disposed in the cell array region and the peripheral circuit region may vary depending on a design placement of the semiconductor memory device.

The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a dielectric constant higher than that of the silicon oxide film or a combination thereof. The high dielectric constant insulating film may include, for example, but not limited to, at least one of metal oxide, metal oxynitride, metal silicon oxide, and metal silicon oxynitride.

A peri-lower conductive pattern 223 and a peri-upper conductive pattern 225 may each include a conductive material. For example, the peri-lower conductive pattern 223 and the peri-upper conductive pattern 225 may each include at least one of a doped semiconductor material, a conductive metal nitride, a conductive metal silicon nitride, a metal carbonitride, a conductive metal silicide, a conductive metal oxide, a two-dimensional material (2D material), a metal, and a metal alloy. Although the peri-gate structure PG is shown to include a plurality of conductive patterns, some example embodiments are not limited thereto.

In the semiconductor device according to some example embodiments, the two-dimensional material may be a metallic material and/or a semiconductor material. The 2D material may include a 2D allotrope or a 2D compound, and may include, but not limited to, at least one of graphene, molybdenum disulfide (MoS₂), molybdenum diselenide (MoSe₂), tungsten diselenide (WSe₂), and tungsten disulfide (WS₂). Since the above-mentioned 2D materials are only listed as an example, the 2D materials that may be included in the semiconductor memory device of some example embodiments are not limited by the above-mentioned materials

A first peri-lower insulating film 227 and a second peri-lower insulating film 228 are disposed on the substrate 100. The first peri-lower insulating film 227 and the second peri-lower insulating film 228 may each be made of an insulating material.

A first peri-wiring line 241a and a peri-contact plug 241b may be disposed in the first peri-lower insulating film 227 and the second peri-lower insulating film 228. Although the first peri-wiring line 241a and the peri-contact plug 241b are shown to be different films, some example embodiments are not limited thereto. A boundary between the first peri-wiring line 241a and the peri-contact plug 241b may not be distinguishable. The first peri-wiring line 241a and the peri-contact plug 241b each include a conductive material.

A first peri-upper insulating film 261 and a second peri-upper insulating film 262 may be disposed on the first peri-wiring line 241a and the peri-contact plug 241b. The first peri-upper insulating film 261 and the second peri-upper insulating film 262 may each be made of an insulating material.

The second peri-wiring line 243 and the peri-via plug 242 are disposed on the first peri-wiring line 241a. The peri-via plug 242 may be disposed in the first peri-upper insulating film 261. The second peri-wiring line 243 may be disposed in the second peri-upper insulating film 262.

The second peri-wiring line 243 and the peri-via plug 242 may be connected to the first peri-wiring line 241a. The peri-via plug 242 may connect the first peri-wiring line 241a and the second peri-wiring line 243. The second peri-wiring line 243 and the peri-via plug 242 each include a conductive material. Although the second peri-wiring line 243 and the peri-via plug 242 are shown to be different films from each other, some example embodiments are not limited thereto. The boundary between the second peri-wiring line 243 and the peri-via plug 242 may not be distinguishable.

The third peri-upper insulating film 263, the fourth peri-upper insulating film 264, and the fifth peri-upper insulating film 265 may be sequentially disposed on the second peri-wiring line 243. The third peri-upper insulating film 263, the fourth peri-upper insulating film 264, and the fifth peri-upper insulating film 265 may each be made of an insulating material.

The fourth peri-upper insulating film 264 may be made of an insulating material different from that of the third peri-upper insulating film 263 and the fifth peri-upper insulating film 265. For example, although the fourth peri-upper insulating film 264 may be made of an oxide-based insulating material, and the third peri-upper insulating film 263 and the fifth peri-upper insulating film 265 may be made of a nitride-based insulating material, some other example embodiments are not limited thereto.

A cell connection plug 244 may be disposed in the third peri-upper insulating film 263, the fourth peri-upper insulating film 264, and the fifth peri-upper insulating film 265. The cell connection plug 244 may be connected to the second peri-wiring line 243. The cell connection plug 244 includes a conductive material. A peri-upper insulating film made of a single film may be disposed in the cell connection plug 244, unlike the shown example.

The bit lines BL are disposed on the peri-gate structure PG. For example, the bit lines BL may be disposed on the fifth peri-upper insulating film 265. For example, the bit lines BL may be in contact with the fifth peri-upper insulating film 265.

The bit line BL may extend long in a second direction D2. Adjacent bit lines BL may be spaced apart in a first direction D1. The bit line BL includes a long side wall extending in the second direction D2, and a short side wall extending in the first direction D1.

Although not shown, each bit line BL may extend from the cell array region to the peripheral circuit region. Ends of each bit line BL may be disposed on the peripheral circuit region of the substrate 100.

Each bit line BL may be disposed on the cell connection plug 244. Each bit line BL may be connected to the cell connection plug 244. Each bit line BL may include, for example, at least one of doped semiconductor material, conductive metal nitride, conductive metal silicon nitride, metal carbonitride, conductive metal silicide, conductive metal oxide, two-dimensional material, metal and metal alloy. Although each bit line BL is shown to be a single film, some example embodiments are not limited thereto.

A cell lower insulating film 171 may be disposed on the fifth peri-upper insulating film 265. The cell lower insulating film 171 is disposed between the bit lines BL spaced apart in the first direction D1. The cell lower insulating film 171 may be made of an insulating material.

A protruding insulating pattern 175 is disposed on the bit line BL and the cell lower insulating film 171. A cell lower etching stop film 173 may be disposed between the protruding insulating pattern 175 and the cell lower insulating film 171. The protruding insulating pattern 175 and the cell lower etching stop film 173 may each be made of an insulating material. The cell lower etching stop film 173 may include a material having an etch selectivity with respect to the protruding insulating pattern 175. For example, the protruding insulating pattern 175 may be made of an oxide-based insulating material, but is not limited thereto. Unlike the shown example, the cell lower etching stop film 173 may not be disposed between the protruding insulating pattern 175 and the cell lower insulating film 171.

The protruding insulating pattern 175 may include a plurality of channel trenches CH_T. Each channel trench CH_T may extend long in the first direction D1. Adjacent channel trenches CH_T may be spaced apart in the second direction D2.

Each channel trench CH_T intersects the bit line BL. One channel trench CH_T may expose a plurality of bit lines BL adjacent in the first direction D1.

A bottom face of each channel trench CH_T may be defined by the bit line BL and the cell lower insulating film 171. The side walls of each channel trench CH_T may be defined by a protruding insulating pattern 175 and a cell lower etching stop film 173. At least a part of the side walls of the channel trench CH_T may be a side wall 175SW of the protruding insulating pattern. When the cell lower etching stop film 173 is not disposed, side walls of each channel trench CH_T may be defined by protruding insulating pattern 175.

A liner film 174 may be disposed on the upper surface BL_US of the bit line BL. The liner film 174 may be in contact with the upper surface BL_US of the bit line BL. The liner film 174 may extend in the second direction D2 along the upper surface BL_US of the bit line BL. The liner film 174 may be disposed in the channel trench CH_T. The liner film 174 may be disposed between the bit line BL and a horizontal part AP_STH of the channel structure AP_ST, which will be described later. Here, the upper surface BL_US of the bit line BL is a face on which a channel structure AP_ST, which will be described later, is formed.

The liner film 174 and the cell lower etching stop film 173 may completely cover the upper surface BL_US of the bit line BL. Specifically, the bit line BL may include a first portion BL1 that overlaps the protruding insulating pattern 175 in a third direction D3, and a second portion BL2 other than the first portion BL1. The cell lower etching stop film 173 may be disposed on the first portion BL1 of the bit line BL. The liner film 174 may be disposed on the second portion BL2 of the bit line BL.

The liner film 174 may include a metal nitride. When the bit line BL includes, for example, a first metal element (e.g., a first element), the liner film 174 may include a metal nitride including the first metal element (e.g., nitrogen as a second element).

In FIG. 5, the upper surface BL_US of the bit line BL may be flat. For example, an upper surface BL1_US of the first portion BL1 and an upper surface BL2_US of the second portion BL2 of the bit line BL may be disposed on the same plane. Here, the upper surface BL2_US of the second portion BL2 of the bit line BL may be a face that is in contact with the liner film 174, in the upper surface BL_US of the bit line BL.

Although the upper surface 174_US of the liner film 174 is shown to be coplanar with the upper surface of the cell lower etching stop film 173, some example embodiments are not limited thereto. For example, the upper surface 174_US of the liner film 174 may be disposed to be higher or lower than the upper surface of the cell lower etching stop film 173.

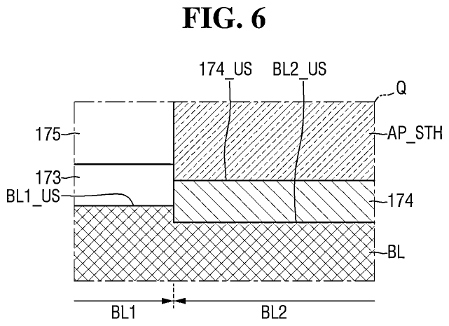

In FIG. 6, the upper surface BL1_US of the first portion BL1 of the bit line BL may be higher than the upper surface BL2_US of the second portion BL2. A part of the liner film 174 may overlap the first portion BL1 of the bit line BL in the second direction D2. The upper surface 174_US of the liner film 174 may be higher than the upper surface BL1_US of the first portion BL1 of the bit line BL.

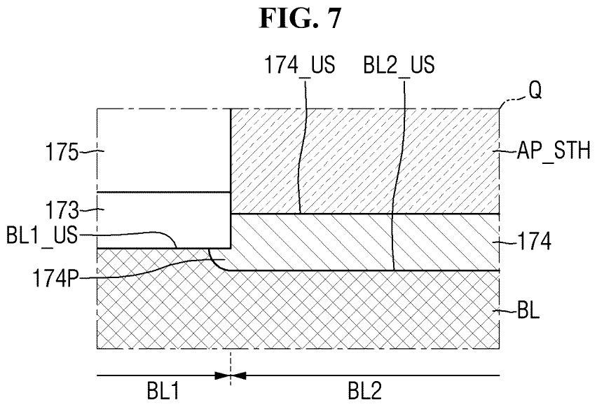

In FIG. 7, the liner film 174 may include a protruding part 174P. The protruding part 174P of the liner film 174 may be disposed in the first portion BL1 of the bit line BL. The protruding part 174P of the liner film 174 may be disposed between the first portion BL1 of the bit line BL and the cell lower etching stop film 173. The protruding part 174P of the liner film 174 may overlap the cell lower etching stop film 173 and the protruding insulating pattern 175 in the third direction D3.

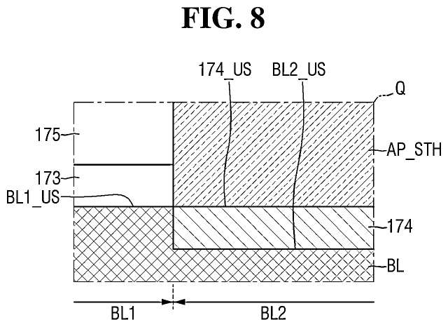

In FIG. 8, the upper surface 174_US of the liner film 174 may be coplanar with the upper surface BL1_US of the first portion BL1 of the bit line BL. In other words, on the basis of the lower face of the bit line BL (e.g., from the lower face of the bit line BL), the height up to the upper surface BL1_US of the first portion BL1 of the bit line BL may be the same as the height up to the upper surface 174_US of the liner film 174.

Referring to FIGS. 1 to 10 again, a channel structure AP_ST may be disposed on each bit line BL. The channel structure AP_ST may be disposed on the liner film 174. The channel structure AP_ST may cover the liner film 174. The channel structure AP_ST may be connected to the bit line BL through the liner film 174. A plurality of channel structures AP_ST may be connected to one bit line BL. A plurality of channel structures AP_ST disposed on one bit line BL are spaced apart in the second direction D2.

The channel structure AP_ST may be disposed in a channel trench CH_T extending in the first direction D1. A plurality of channel structures AP_ST may be disposed in the single channel trench CH_T. The plurality of channel structures AP_ST disposed in the channel trenches CH_T are spaced apart in the first direction D1.

For example, the channel structures AP_ST may be arranged two-dimensionally along the first direction D1 and the second direction D2 that intersect each other. Although not limited thereto, in some example embodiments the first direction D1 may be orthogonal to the second direction D2 along a same planar surface, and the third direction D3 may extend in a vertical direction from the planar surface.

The channel structure AP_ST may extend along the side walls and bottom face of the channel trench CH_T. In a cross-section taken in the second direction D2, the channel structure AP_ST may have a “U” shape.

The channel structure AP_ST may include a horizontal part AP_STH, a first vertical part AP_STV1, and a second vertical part AP_STV2. The first vertical part AP_STV1 of the channel structure and the second vertical part AP_STV2 of the channel structure may protrude from the horizontal part AP_STH of the channel structure in the third direction D3.

The horizontal part AP_STH of the channel structure may extend along the bottom face of the channel trench CH_T and the upper surface 174_US of the liner film 174. The horizontal part AP_STH of the channel structure may extend along the upper surface 174_US of the liner film 174 in a cross-section taken in the second direction D2. The horizontal part AP_STH of the channel structure may be connected to the bit line BL through the liner film 174. For example, the horizontal part AP_STH of the channel structure and the liner film 174 may be sequentially disposed on the upper surface BL_US of the bit line BL.

The first vertical part AP_STV1 of the channel structure and the second vertical part AP_STV2 of the channel structure may extend along side walls of the channel trench CH_T. In a cross-section taken in the second direction D2, the first vertical part AP_STV1 of the channel structure and the second vertical part AP_STV2 of the channel structure may each extend along the side wall 175SW of the protruding insulating pattern 175.

The channel structure AP_ST may include an oxide semiconductor material. The channel structure AP_ST may include, for example, metal oxide. As an example, the channel structure AP_ST may be an amorphous metal oxide film. As still another example, the channel structure AP_ST may be a polycrystalline metal oxide film. As yet another example, the channel structure AP_ST may be in a state of a combination of the amorphous metal oxide film and the polycrystalline metal oxide film. As still another example, the channel structure AP_ST may be a CAAC (c-axis aligned crystalline) metal oxide film.

The channel structure AP_ST may include, for example, but not limited to, at least one of indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, and In—Hf—Al—Zn-based oxide.

Here, the In—Ga—Zn-based oxide means an oxide that has In, Ga, and Zn as main components, but does not mean a ratio of In, Ga, and Zn. That is, taking IGZO (indium gallium zinc oxide) as an example, the channel structure AP_ST may include IGZO (indium gallium zinc oxide, InₓGa_{y}Zn_{z}O). IGZO (In:Ga:Zn=1:1:1) containing indium, gallium and zinc in the same ratio may be an In—Ga—Zn-based oxide. Ga-rich IGZO may have a higher ratio of gallium than IGZO (In:Ga:Zn=1:1:1), and a lower ratio of indium than IGZO (In:Ga:Zn=1:1:1). Ga-rich IGZO may also be an In—Ga—Zn-based oxide. Further, In-rich IGZO may have a higher ratio of indium than IGZO (In:Ga:Zn=1:1:1) and a lower ratio of gallium than IGZO (In:Ga:Zn=1:1:1). In-rich IGZO may also be an In—Ga—Zn-based oxide.

Although the above description has been made using IGZO, some example embodiments are not limited thereto. The above description may be applied when the channel structures AP_ST each include a ternary or higher metal oxide. Also, when the channel structure AP_ST includes the In—Ga—Zn-based oxide, the channel structure AP_ST may further include a doped metal element other than In, Ga, and Zn.

The channel structure AP_ST may include a first channel pattern AP1, a second channel pattern AP2, and a connecting channel pattern AP_CP. The connecting channel pattern AP_CP connects the first channel pattern AP1 and the second channel pattern AP2. The first channel pattern AP1 and the second channel pattern AP2 are spaced apart in the second direction D2.

The first channel pattern AP1, the second channel pattern AP2, and the connecting channel pattern AP_CP are disposed on the bit line BL and the liner film 174. The first channel pattern AP1 and the second channel pattern AP2 are connected to the bit line BL. The first channel pattern AP1 and the second channel pattern AP2 may be in contact with the upper surface 174_US of the liner film 174. The liner film 174 may be disposed between the connecting channel pattern AP_CP and the bit line BL.

The first channel pattern AP1 may include a part of the horizontal part AP_STH of the channel structure and a first vertical part AP_STV1 of the channel structure. A part of the horizontal part AP_STH of the channel structure may be a horizontal part of the first channel pattern AP1. The first vertical part AP_STV1 of the channel structure may be a vertical part of the first channel pattern AP1.

The second channel pattern AP2 may include another part of the horizontal part AP_STH of the channel structure, and the second vertical part AP_STV2 of the channel structure. Another part of the horizontal part AP_STH of the channel structure may be the horizontal part of the second channel pattern AP2. The second vertical part AP_STV2 of the channel structure may be the vertical part of the second channel pattern AP2.

The connecting channel pattern AP_CP includes the rest of the horizontal part AP_STH of the channel structure.

The first channel pattern AP1, the second channel pattern AP2, and the connecting channel pattern AP_CP may be distinguished on the basis of a first word line WL1 and a second word line WL2, which will be described later. In FIG. 4, the first word line WL1 will be described as an example. The first word line WL1 may include an inner wall that faces the side wall 175SW of the protruding insulating pattern, and an outer wall opposite to the inner wall in the second direction D2. A boundary between the first channel pattern AP1 and the connecting channel pattern AP_CP may be an extension line of the outer wall of the first word line WL1 extending in the third direction D3.

The first word line WL1 and the second word line WL2 may be disposed on the channel structure AP_ST. The first word line WL1 and the second word line WL2 may be disposed in the channel trench CH_T.

Each of the first word line WL1 and the second word line WL2 may extend in the first direction D1. The first word line WL1 and the second word line WL2 may be alternately arranged in the second direction D2. The first word line WL1 is spaced apart from the second word line WL2 in the second direction D2.

The first word line WL1 and the second word line WL2 are spaced apart from the bit line BL in the third direction D3. The first word line WL1 and the second word line WL2 intersect the bit line BL.

The first word line WL1 and the second word line WL2 are disposed on the horizontal part AP_STH of the channel structure. The first word line WL1 and the second word line WL2 are disposed between the first vertical part AP_STV1 of the channel structure and the second vertical part AP_STV2 of the channel structure.

The first word line WL1 is disposed on the first channel pattern AP1. The second word line WL2 is disposed on the second channel pattern AP2. The first word line WL1 and the second word line WL2 are disposed between the first channel pattern AP1 and the second channel pattern AP2. The first channel pattern AP1 is closer to the first word line WL1 than the second word line WL2. The second channel pattern AP2 is closer to the second word line WL2 than the first word line WL1.

Each of the first word line WL1 and the second word line WL2 may have a width in the second direction D2. The width of the first word line WL1 in the portion that overlaps the channel structure AP_ST in the third direction D3 may be different from the width of the first word line WL1 in the portion that does not overlap the channel structure AP_ST. The width of the second word line WL2 in the portion that overlaps the channel structure AP_ST in the third direction D3 may be different from the width of the second word line WL2 in the portion that does not overlap the channel structure AP_ST.

For example, each of the first word line WL1 and the second word line WL2 may include a first portion WLa of the word line, and a second portion WLb of the word line. The width of the first portion WLa of the word line in the second direction D2 may be smaller than the width of the second portion WLb of the word line in the second direction D2. As an example, the first portion WLa of the word line may be disposed on the channel structure AP_ST. The first portion WLa of the word line may be disposed on the first channel pattern AP1 and the second channel pattern AP2.

Each of the first word line WL1 and the second word line WL2 may include the first portion WLa of the word line and the second portion WLb of the word line that are disposed alternately along the first direction D1. Each channel structure AP_ST may be disposed between second portions WLb of the word lines adjacent in the first direction D1. In the first word line WL1, each first active pattern AP1 may be disposed between the second portions WLb of the word lines adjacent in the first direction D1. In the second word line WL2, each second active pattern AP2 may be disposed between the second portions WLb of word lines adjacent in the first direction D1.

The channel structure AP_ST is not disposed below the second portion WLb of the word line. The height of the first portion WLa of the word line is smaller than the height of the second portion WLb of the word line.

The first and second word lines WL1 and WL2 include a conductive material, and may include, for example, at least one of doped polysilicon, conductive metal nitride, conductive metal silicon nitride, metal carbonitride, conductive metal silicide, conductive metal oxide, two-dimensional material, metal and metal alloy.

The first and second word lines WL1 and WL2 may include an upper surface WL_US and a lower face that are opposite to each other in the third direction D3. The lower faces of the first and second word lines WL1 and WL2 face the bit line BL.

In FIG. 4, the upper surface WL_US of the first and second word lines WL1 and WL2 may be a plane. In FIG. 9, the upper surface WL_US of the first and second word lines WL1 and WL2 may be convexly rounded. In FIG. 10, the upper surface WL_US of the first and second word lines WL1 and WL2 may be concavely rounded.

On the basis of the upper surface of the bit line BL, the upper surface WL_US of the first and second word lines WL1 and WL2 may be higher than the uppermost parts of the vertical parts AP_STV1 and AP_STV2 of the channel structure. The uppermost parts of the channel patterns AP1 and AP2 may be the uppermost parts of the vertical parts AP_STV1 and AP_STV2 of the channel structure. A height H1 from the upper surface BL_US of the bit line BL to the uppermost parts of the vertical parts AP_STV1 and AP_STV2 of the channel structure may be smaller than a height H2 from the upper surface BL_US of the bit line BL to the upper surface WL_US of the first and second word lines WL1 and WL2.

The gate insulating film GOX may be disposed between the first word line WL1 and the channel structure AP_ST, and between the second word line WL2 and the channel structure AP_ST. The gate insulating film GOX may be disposed between the first word line WL1 and the first active pattern AP1, and between the second word line WL2 and the second active patterns AP2. The gate insulating film GOX may extend in the first direction D1 along with the first word line WL1 and the second word line WL2.

The gate insulating film GOX may extend along the first vertical part AP_STV1 of the channel structure. The gate insulating film GOX may extend along the second vertical part AP_STV2 of the channel structure. In the semiconductor memory device according to some example embodiments, the gate insulating film GOX may not be disposed on the horizontal part AP_STH of the channel structure that does not overlap the first word line WL1 and the second word line WL2 in the third direction D3. From viewpoint of the cross-sectional view, the gate insulating film GOX between the first word line WL1 and the channel structure AP_ST may be separated from the gate insulating film GOX between the second word line WL2 and the channel structure AP_ST.

The gate insulating film GOX may include a silicon oxide film, a silicon oxynitride film, a high dielectric constant insulating film having a higher dielectric constant than the silicon oxide film, or a combination thereof.

A part of the gate insulating film GOX may protrude in the third direction D3 beyond the upper surfaces WL_US of the first and second word lines WL1 and WL2. A part of the gate insulating film GOX may protrude in the third direction D3 beyond the uppermost parts of the vertical parts AP_STV1 and AP_STV2 of the channel structure.

A height H4 from the upper surface BL_US of the bit line BL to the uppermost part GOX_UUS of the gate insulating film may be greater than the height H1 from the upper surface BL_US of the bit line BL to the uppermost part of the vertical parts AP_STV1 and AP_STV2 of the channel structure. The height H4 from the upper surface of the bit line BL to the uppermost part GOX_UUS of the gate insulating film may be greater than the height H2 from the upper surface of the bit line BL to the upper surface WL_US of the word lines WL1 and WL2.

A gate separation pattern GSS may be disposed on the bit line BL and the cell lower insulating film 171. The gate separation pattern GSS may be disposed inside the channel trench CH_T. The gate separation pattern GSS may be disposed on the channel structure AP_ST, the first word line WL1 and the second word line WL2.

In the semiconductor memory device according to some example embodiments, the gate separation pattern GSS may be in contact with the channel structure AP_ST. The gate separation pattern GSS may be disposed on the connecting channel pattern AP_CP. The gate separation pattern GSS may be in contact with the horizontal part AP_STH of the channel structure. The gate separation pattern GSS may be spaced apart from the bit line BL in the third direction D3.

The gate separation pattern GSS may be disposed between the first word line WL1 and the second word line WL2 adjacent in the second direction D2. The first word line WL1 and the second word line WL2 may be separated by the gate separation pattern GSS. The gate separation pattern GSS may extend in the first direction D1 between the first word line WL1 and the second word line WL2.

The first word line WL1 may be disposed between the gate separation pattern GSS and the channel structure AP_ST. The second word line WL2 may be disposed between the gate separation pattern GSS and the channel structure AP_ST. The first word line WL1 may be disposed between the gate separation pattern GSS and the first channel pattern AP1. The second word line WL2 may be disposed between the gate separation pattern GSS and the second channel pattern AP2.

The gate separation pattern GSS may include a horizontal part and a protruding part. The protruding part of the gate separation pattern GSS may protrude in the third direction D3 from the horizontal part of the gate separation pattern GSS toward the bit line BL. The protruding part of the gate separation pattern GSS may be closer to the bit line BL than the horizontal part of the gate separation pattern GSS. The horizontal part of the gate separation pattern GSS may be disposed on the upper surface WL_US of the first and second word lines WL1 and WL2. In a cross-sectional view, the gate separation pattern GSS may have a “T” shape.

The gate separation pattern GSS may include a gate separation liner 151, a gate separation filling film 153 and a gate separation capping film 155. The gate separation liner 151 may extend along upper surfaces WL_US of the first and second word lines WL1 and WL2 and outer walls of the first and second word lines WL1 and WL2. The gate separation liner 151 may extend along the horizontal part AP_STH of the channel structure. The gate separation liner 151 may be in contact with the connecting channel pattern AP_CP. The gate separation liner 151 may extend along the gate insulating film GOX protruding beyond the upper surface WL_US of the first and second word lines WL1 and WL2. Unlike the shown example, in some example embodiments the gate separation liner 151 may not extend along the gate insulating film GOX protruding beyond the upper surface WL_US of the first and second word lines WL1 and WL2.

The gate separation filling film 153 may be disposed on the gate separation liner 151. The gate separation capping film 155 may be disposed on the gate separation filling film 153. The gate separation liner 151, the gate separation filling film 153, and the gate separation capping film 155 may each be made of an insulating material. Unlike the shown example, in some example embodiments the gate separation pattern GSS may be a single film.

On the basis of the upper surface of the bit line BL, the upper surface GSS_US of the gate separation pattern may be disposed at the same height as the upper surface of the protruding insulating pattern 175, but is not limited thereto.

A height H3 from the upper surface BL_US of the bit line BL to the upper surface GSS_US of the gate separation pattern may be greater than the height H1 from the upper surface BL_US of the bit line BL to the uppermost parts of the vertical parts AP_STV1 and AP_STV2 of the channel structure. The height H3 from the upper surface BL_US of the bit line BL to the upper surface GSS_US of the gate separation pattern may be greater than the height H2 from the upper surface BL_US of the bit line BL to the upper surfaces WL_US of the word lines WL1 and WL2.

The height H3 from the upper surface BL_US of the bit line BL to the upper surface GSS_US of the gate separation pattern is shown as being the same as the height H4 from the upper surface BL_US of the bit line BL to the uppermost part GOX_UUS of the gate insulating film, but is not limited thereto.

The landing pads LP may be disposed on the channel structure AP_ST. The landing pads LP are connected to the first vertical part AP_STV1 of the channel structure and the second vertical part AP_STV2 of the channel structure.

The landing pads LP may be disposed on the first channel pattern AP1 and the second channel pattern AP2. The landing pads LP are connected to the first channel pattern AP1 and the second channel pattern AP2.

From the planar viewpoint, the landing pads LP may have various shapes such as a circular shape, an oval shape, a rectangular shape, a square shape, a rhombic shape, and a hexagonal shape.

The landing pads LP may include a horizontal part LP_H and a protruding part LP_P. The horizontal part LP_H of the landing pad may be disposed on the upper surface of the protruding insulating pattern 175 and the upper surface GSS_US of the gate separation pattern. The protruding part LP_P of the landing pad may protrude in the third direction D3 from the horizontal part LP_H of the landing pad toward the bit line BL.

On the basis of the upper surface BL_US of the bit line BL, the lowermost part of the landing pad LP may be lower than the upper surface GSS_US of the gate separation pattern. In other words, the protruding part LP_P of the landing pad is disposed between the protruding insulating pattern 175 and the gate separation pattern GSS. The height from the upper surface BL_US of the bit line BL to the lowermost part of the landing pad LP may be smaller than the height H4 from the upper surface BL_US of the bit line BL to the uppermost part GOX_UUS of the gate insulating film.

Pad separation insulating patterns 235 may be disposed between the landing pads LP. From the planar viewpoint, the landing pads LP may be arranged in the form of a matrix along the first direction D1 and the second direction D2. The upper surface of the landing pad LP may coplanar with the upper surface of the pad separation insulating pattern 235, but is not limited thereto.

The landing pad LP includes a conductive material. The landing pad LP may include, for example, at least one of doped polysilicon, conductive metal nitride, conductive metal silicon nitride, metal carbonitride, conductive metal silicide, conductive metal oxide, two-dimensional material, metal and metal alloy.

The data storage patterns DSP may be disposed on the landing pads LP, respectively. The data storage patterns DSP may be connected to the first vertical part AP_STV1 of the channel structure and the second vertical part AP_STV2 of the channel structure. The data storage patterns DSP may be connected to each of the first and second channel patterns AP1 and AP2.

The data storage patterns DSP may be arranged in the form of a matrix along the first direction D1 and the second direction D2, as shown in FIG. 1. The data storage patterns DSP may completely or partially overlap the landing pads LP in the third direction D3. The data storage patterns DSP may be in contact with all or part of the upper surfaces of the landing pads LP.

As an example, the data storage patterns DSP may be a capacitor. The first channel pattern AP1 may be connected to the first capacitor. The second channel pattern AP2 may be connected to the second capacitor.

The data storage patterns DSP may include a capacitor dielectric film 253 interposed between the storage electrodes 251 and the plate electrode 255. In this case, the storage electrode 251 may be in contact with the landing pad LP. The first channel pattern AP1 may be connected to a first capacitor including a storage electrode 251, the capacitor dielectric film 253 and the plate electrode 255, and the second channel pattern AP2 may be connected to the second capacitor including another storage electrode 251, the capacitor dielectric film 253 and the plate electrode 255. From the planar viewpoint, the storage electrode 251 may have various shapes such as a circular shape, an oval shape, a rectangular shape, a square shape, a rhombic shape, and a hexagonal shape. The data storage patterns DSP may completely overlap or partially overlap the landing pads LP. The data storage patterns DSP may be in contact with all or part of the upper surfaces of the landing pads LP. The storage electrodes 251 may penetrate the cell upper etching stop film 247. The cell upper etching stop film 247 may be made of an insulating material.

In contrast, in some example embodiments the data storage patterns DSP may be a variable resistance pattern that may be switched between two resistance states by electrical pulses applied to the memory elements. For example, the data storage patterns DSP may include a phase-change material, perovskite compounds, transition metal oxide, magnetic materials, ferromagnetic materials or antiferromagnetic materials.

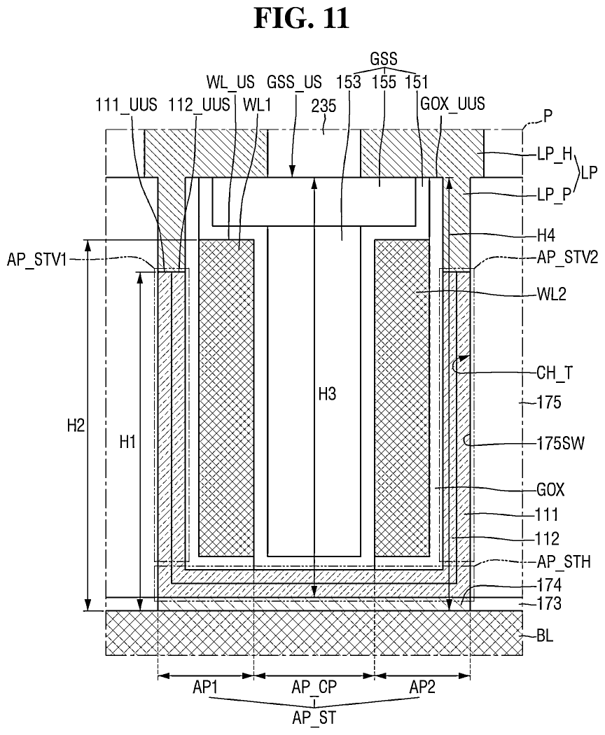

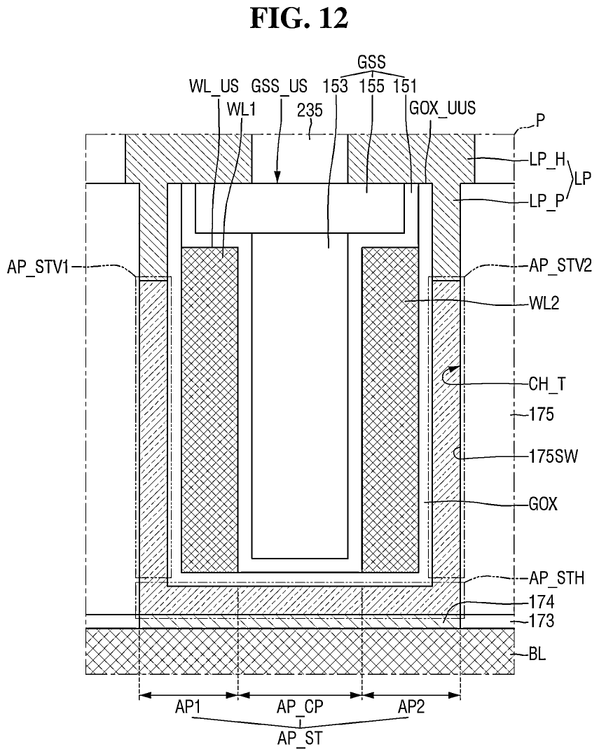

FIG. 11 is a diagram for explaining a semiconductor memory device according to some example embodiments. FIG. 12 is a diagram for explaining a semiconductor memory device according to some example embodiments. For convenience of explanation, the points different from those explained in FIGS. 1 to 10 will be mainly explained. For reference, FIGS. 11 and 12 are enlarged views of a portion P of FIG. 2.

Referring to FIG. 10, in the semiconductor memory device according to some example embodiments, the gate separation pattern GSS may not be in contact with the channel structure AP_ST.

For example, a part of the gate insulating film GOX may be disposed between the gate separation pattern GSS and the channel structure AP_ST. From the viewpoint of the cross-sectional view, in some example embodiments the gate insulating film GOX between the first word line WL1 and the channel structure AP_ST may be connected to the gate insulating film GOX between the second word line WL2 and the channel structure AP_ST, such as shown in FIG. 12 for example.

Referring to FIG. 11, in the semiconductor device according to some example embodiments, the channel structure AP_ST may include a first metal oxide pattern 111 and a second metal oxide pattern 112.

The first metal oxide pattern 111 may extend along the bottom face and side walls of the channel trench CH_T. The first metal oxide pattern 111 may be in contact with the liner film 174.

The second metal oxide pattern 112 may be disposed on the first metal oxide pattern 111. The second metal oxide pattern 112 may extend along the bottom face and side walls of the channel trench CH_T.

Each of the first metal oxide pattern 111 and the second metal oxide pattern 112 may include an oxide semiconductor material.

In the semiconductor memory device according to some example embodiments, the first metal oxide pattern 111 and the second metal oxide pattern 112 may each include amorphous metal oxide. The composition of the first metal oxide pattern 111 may be different from the composition of the second metal oxide pattern 112.

As an example, the first metal oxide pattern 111 and the second metal oxide pattern 112 may include different materials from each other. The composition of the first metal oxide pattern 111 may be different from the composition of the second metal oxide pattern 112.

As another example, the first metal oxide pattern 111 and the second metal oxide pattern 112 may include the same material. For example, the first metal oxide pattern 111 and the second metal oxide pattern 112 may include IGZO (indium gallium zinc oxide, InₓGa_{y}Zn_{z}O). However, composition ratios of indium (In), gallium (Ga), and zinc (Zn) included in IGZO may be different in the first metal oxide pattern 111 and the second metal oxide pattern 112.

As yet another example, the first metal oxide pattern 111 and the second metal oxide pattern 112 may each include impurity-doped indium zinc oxide (IZO). Impurities doped into IZO (indium zinc oxide) in the first metal oxide pattern 111 may be different from impurities doped into IZO (indium zinc oxide) in the second metal oxide pattern 112. In such a case, the composition of the first metal oxide pattern 111 may be different from the composition of the second metal oxide pattern 112.

In the semiconductor memory device according to some example embodiments, one of the first metal oxide pattern 111 and the second metal oxide pattern 112 may include an amorphous metal oxide, and the other may include CAAC (c-axis aligned crystalline) IGZO.

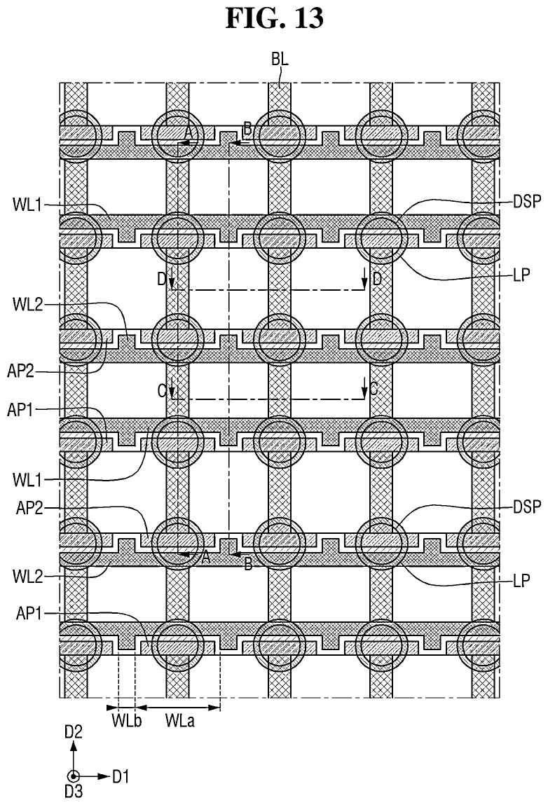

FIGS. 13 to 17 are diagrams for explaining a semiconductor memory device according to some example embodiments. For convenience of explanation, the explanation will focus on points that are different from those explained using FIGS. 1 to 10.

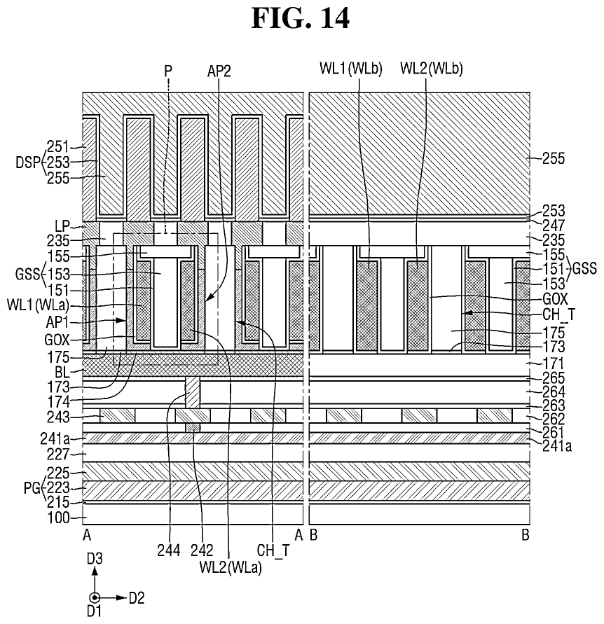

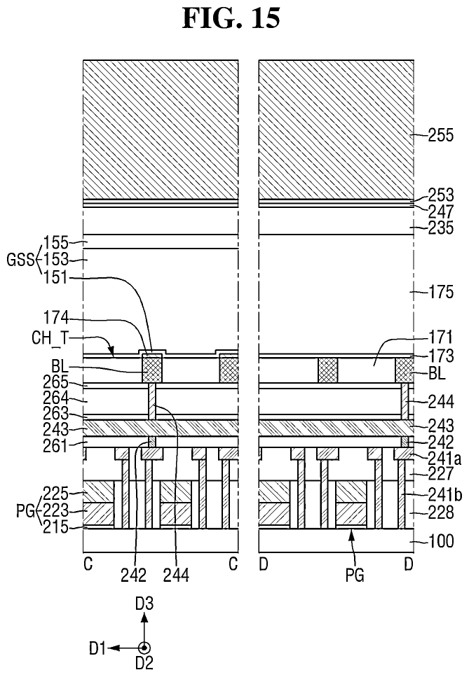

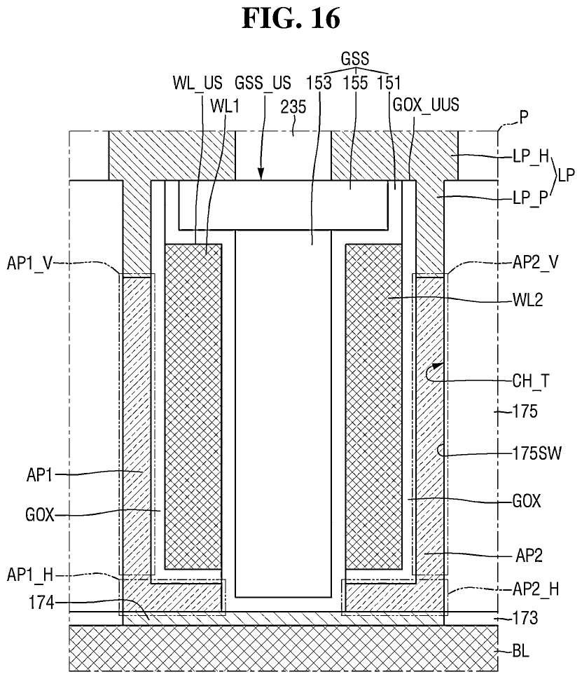

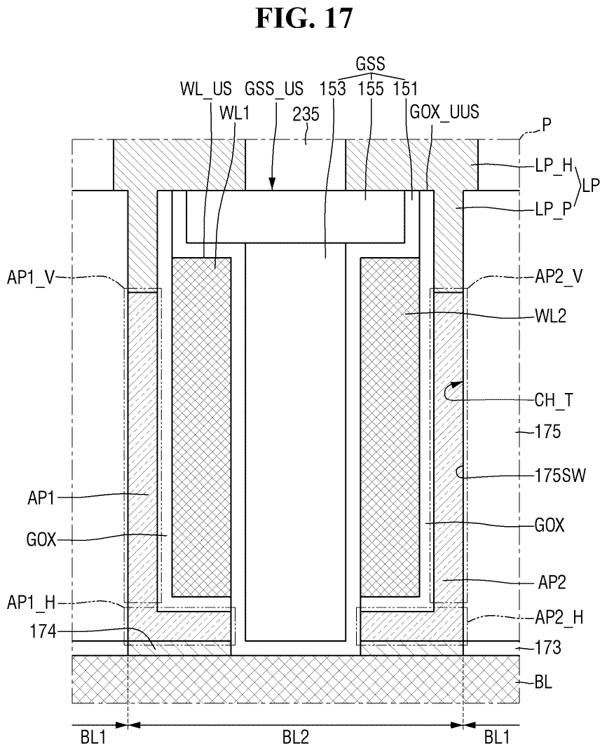

For reference, FIG. 13 is a layout diagram for explaining a semiconductor memory device according to some example embodiments. FIG. 14 is a cross-sectional view taken along A-A and B—B of FIG. 13. FIG. 15 is a cross-sectional view taken along C-C and D-D of FIG. 13. FIGS. 16 and 17 are enlarged views of a portion P of FIG. 14.

Referring to FIGS. 13 to 17, in the semiconductor memory device according to some example embodiments, the first channel pattern AP1 and the second channel pattern AP2 spaced apart in the second direction D2 are not connected to each other inside the channel trench CH_T.

The first channel pattern AP1 may include a horizontal part AP1_H extending along the upper surface of the bit line BL, and a vertical part AP1_V extending along side walls 175SW of the protruding insulating pattern. The vertical part AP1_V of the first channel pattern may protrude in the third direction D3 from the horizontal part AP1_H of the first channel pattern.

The second channel pattern AP2 may include a horizontal part AP2_H extending along the upper surface of the bit line BL, and a vertical part AP2_V extending along side walls 175SW of the protruding insulating pattern. The vertical part AP2_V of the second channel pattern may protrude in the third direction D3 from the horizontal part AP2_H of the second channel pattern.

The gate separation pattern GSS may be in contact with the upper surface 174_US of the liner film 174. The horizontal part AP2_H of the second channel pattern and the horizontal part AP1_H of the first channel pattern may be spatially separated by the gate separation pattern GSS. The gate separation liner 151 may be in contact with the liner film 174.

In FIG. 17, the gate separation pattern GSS may separate the liner film 174. The liner films 174 may be spaced apart in the second direction D2. The liner film 174 may be separated by the gate separation patterns GSS. The gate separation liner 151 may be disposed between the spaced liner films 174.

The liner film 174 may partially cover the upper surface BL_US of the bit line BL. The liner film 174 may be disposed between the bit line BL and the horizontal part AP1_H of the first channel pattern AP1. The liner film 174 may be disposed between the bit line BL and the horizontal part AP2_H of the second channel pattern AP2.

The bit line BL may include a first portion BL1 and a second portion BL2. The second portion BL2 of the bit line BL may include a first sub-region and a second sub-region. The first sub-region may be a region in which the bit line BL, the first channel pattern AP1 and the second channel pattern AP2 overlap in the third direction D3. The second sub-region may be a remaining region of the second portion BL2 other than the first sub-region. The liner film 174 may be disposed on the first sub-region, but may not be disposed on the second sub-region.

The gate separation pattern GSS may be in contact with the upper surface BL_US of the bit line BL. The horizontal part AP2_H of the second channel pattern and the horizontal part AP1_H of the first channel pattern may be spatially separated by the gate separation pattern GSS. The gate separation liner 151 may be in contact with the liner film 174.

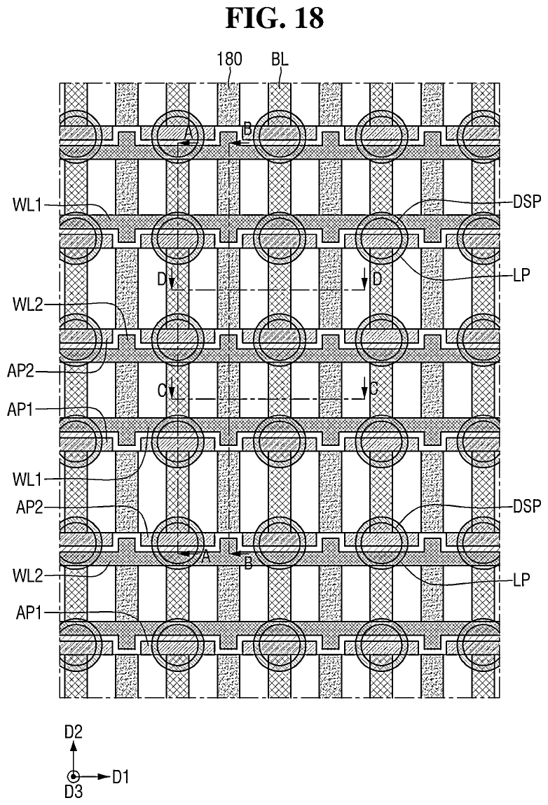

FIGS. 18 to 20 are diagrams for explaining a semiconductor memory device according to some example embodiments. For convenience of explanation, the explanation will focus on points that are different from those explained using FIGS. 1 to 10.

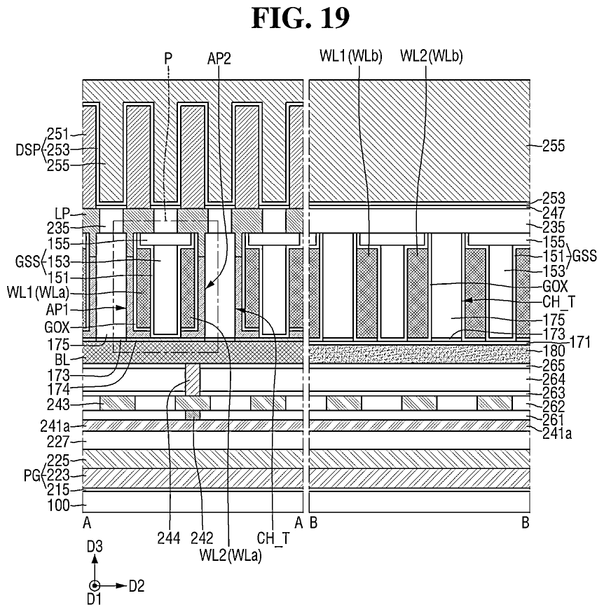

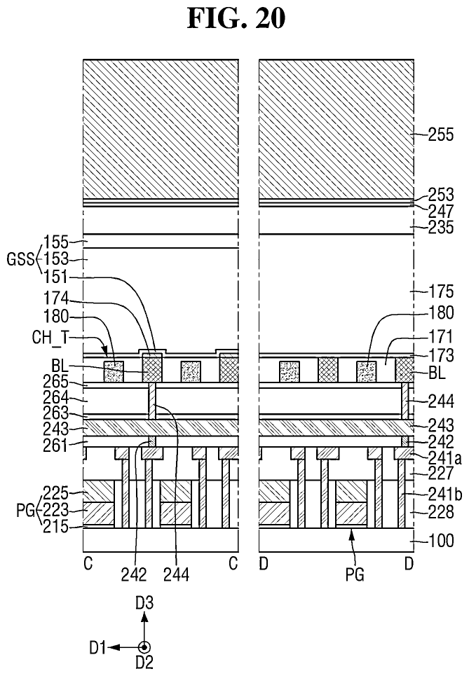

For reference, FIG. 18 is a layout diagram for explaining a semiconductor memory device according to some example embodiments. FIG. 19 is a cross-sectional view taken along A-A and B—B of FIG. 18. FIG. 20 is a cross-sectional view taken along C-C and D-D of FIG. 18.

Referring to FIGS. 18 to 20, the semiconductor memory device according to some example embodiments may further include a shielding structure 180.

The shielding structure 180 may extend in the second direction D2. The shielding structure 180 may be spaced apart from the bit line BL in the first direction D1. The shielding structure 180 may be arranged alternately with the bit line BL in the first direction D1.

The shielding structure 180 may be disposed inside the cell lower insulating film 171. The upper surface of the shielding structure 180 may be lower than the upper surface BL_US of the bit line BL.

The shielding structure 180 may include a conductive material, as an example. As another example, the shielding structure 180 may include a conductive material, and may include an air gap or a void inside the conductive material.

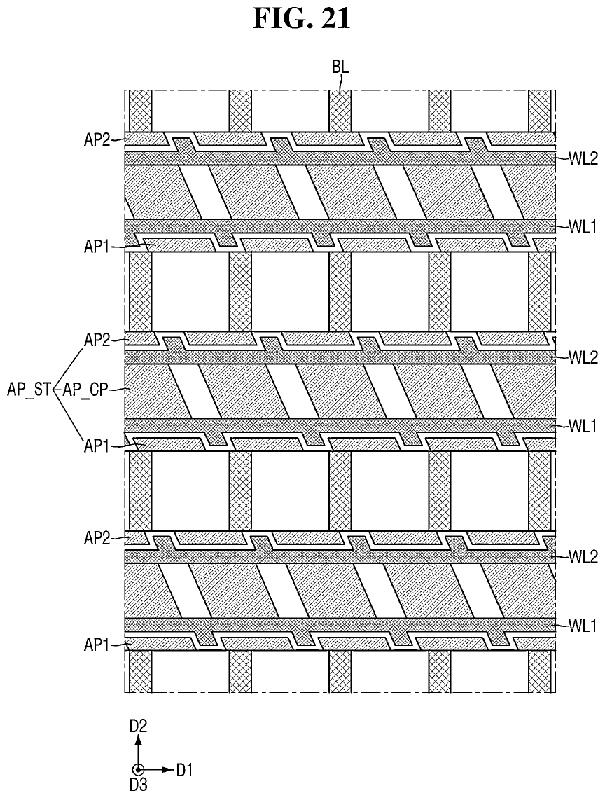

FIGS. 21 to 24 are diagrams for explaining a semiconductor memory device according to some example embodiments. For convenience of explanation, the explanation will focus on points that are different from those explained using FIGS. 1 to 10.

Referring to FIG. 21, in the semiconductor memory device according to some example embodiments, the first channel pattern AP1 and the second channel pattern AP2 may be arranged alternately in a diagonal direction with respect to the first direction D1 and the second direction D2. Here, the diagonal direction may be parallel to the upper surface of the substrate 100.

The channel structure AP_ST may be formed to be twisted in the diagonal direction. From the planar viewpoint, the first channel pattern AP1, the second channel pattern AP2, and the connecting channel pattern AP_CP may each have a parallelogram shape or a rhombic shape.

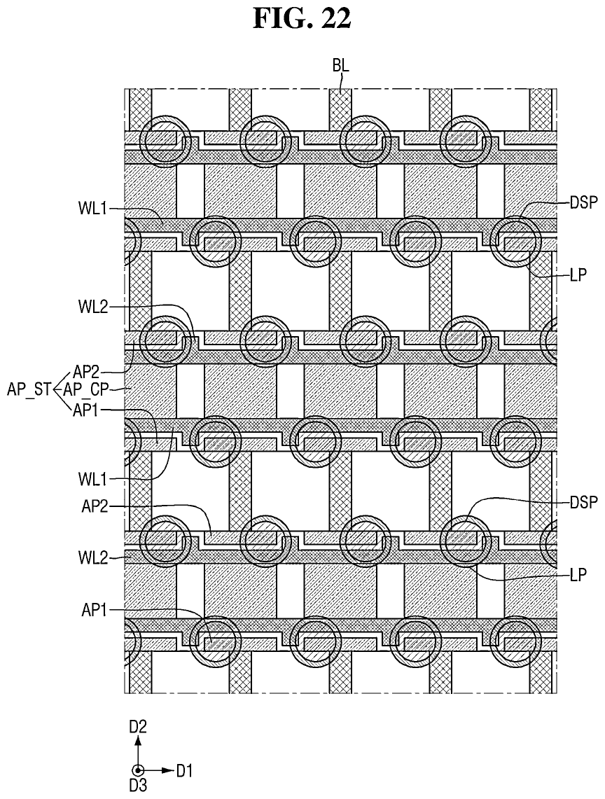

Referring to FIG. 22, in the semiconductor memory device according to some example embodiments, the landing pads LP and the data storage patterns DSP may be arranged in a zigzag or honeycomb form from the planar viewpoint.

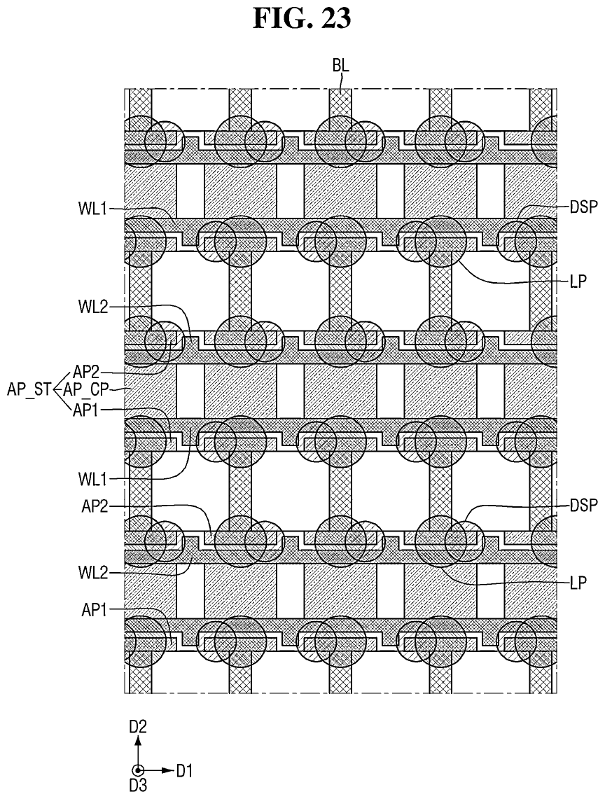

Referring to FIG. 23, in the semiconductor memory device according to some example embodiments, the data storage patterns DSP may be disposed to be dislocated from the landing pads LP from the planar viewpoint.

Each data storage pattern DSP may be in contact with a part of the landing pad LP.

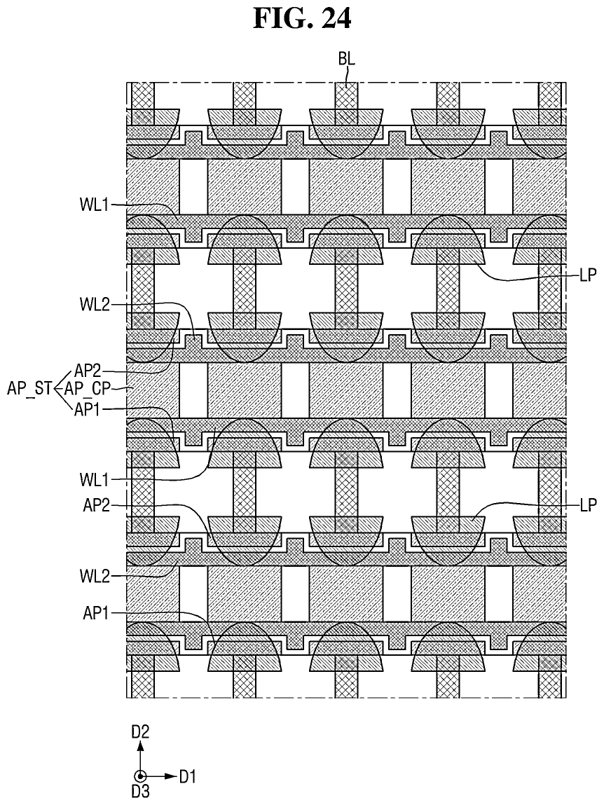

Referring to FIG. 24, in the semiconductor memory device according to some example embodiments, each of the landing pads LP disposed on the first channel pattern AP1 and the second channel pattern AP2 may have a semicircular shape or a semi-elliptical shape from the planar viewpoint.

From the planar viewpoint, the landing pads LP may be disposed symmetrically with each other.

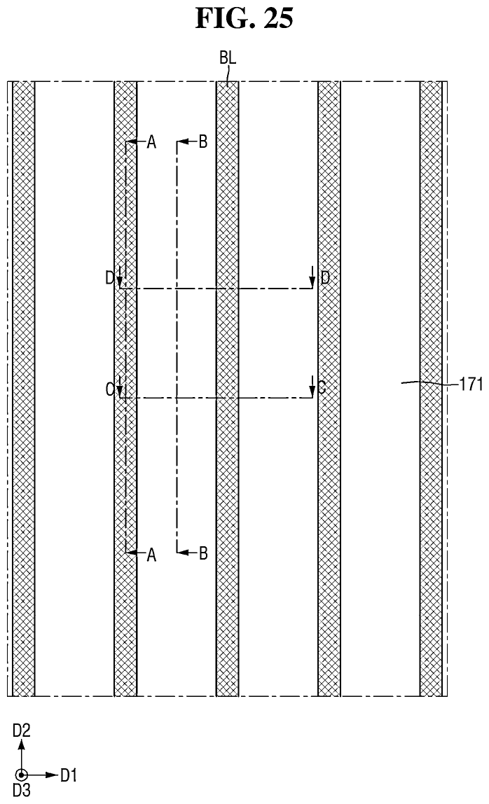

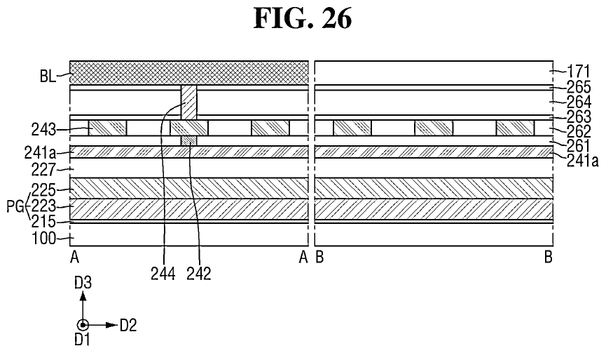

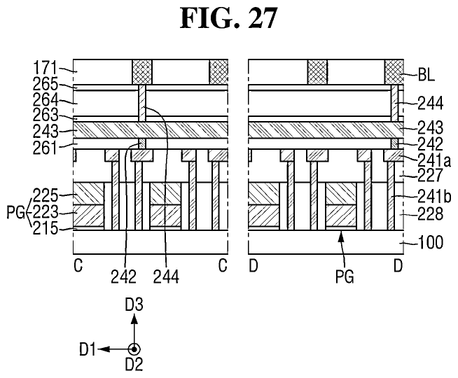

FIGS. 25 to 39 are diagrams for explaining a method for fabricating the semiconductor memory device according to some example embodiments.

Referring to FIGS. 25 to 27, the peri-gate structure PG may be formed on the substrate 100.

The first peri-wiring line 241a and the peri-contact plug 241b may be formed on the substrate 100.

The peri-upper insulating films 261, 262, 263, 264 and 265 may be sequentially formed on the first peri-wiring line 241a and the peri-contact plug 241b. The second peri-wiring line 243, the peri-via plug 242 and the cell connection plug 244 may be formed inside the peri-upper insulating films 261, 262, 263, 264 and 265.

The bit lines BL may then be formed on the fifth peri-upper insulating film 265. The bit line BL may extend long on the substrate 100 in the second direction D2. The cell lower insulating film 171 may be formed on the fifth peri-upper insulating film 265. The cell lower insulating film 171 may expose the upper surface of the bit line BL.

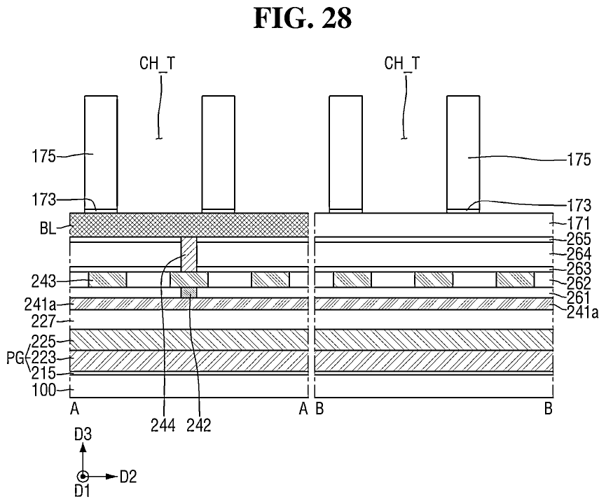

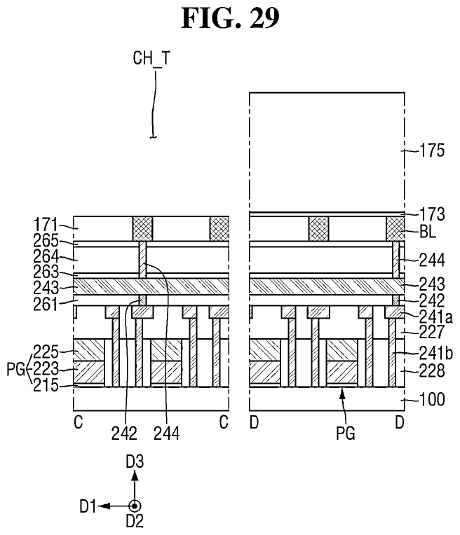

Referring to FIGS. 28 and 29, the protruding insulating pattern 175 may be formed on the substrate 100. For example, the protruding insulating pattern 175 may be formed on the bit line BL and the cell lower insulating film 171.

The cell lower etching stop film 173 may be formed between the protruding insulating pattern 175 and the cell lower insulating film 171, but is not limited thereto.

The protruding insulating pattern 175 may include a plurality of channel trenches CH_T extending in the first direction D1. The channel trench CH_T may intersect the bit line BL. The channel trench CH_T may expose the bit line BL.

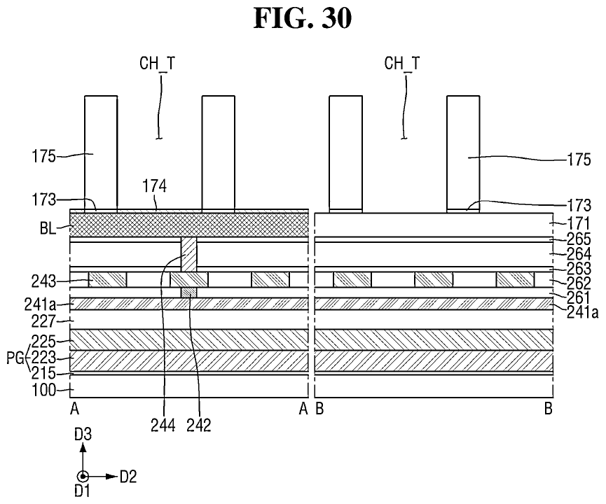

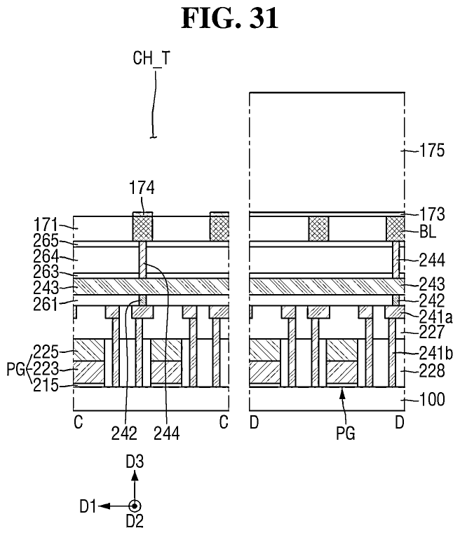

Referring to FIGS. 30 and 31, the liner film 174 may be formed on the upper surface BL_US of the bit line BL.

For example, the liner film 174 may be formed on the upper surface BL_US of the bit line BL exposed by the channel trench CH_T by a plasma nitriding process. The plasma nitriding process may include, for example, but not limited to, any one of a physical vapor deposition (PVD) method, a chemical vapor deposition (CVD) method, an atomic layer deposition (ALD) method, and an ion implantation method.

The liner film 174 and the cell lower etching stop film 173 may completely cover the upper surface BL_US of the bit line BL.

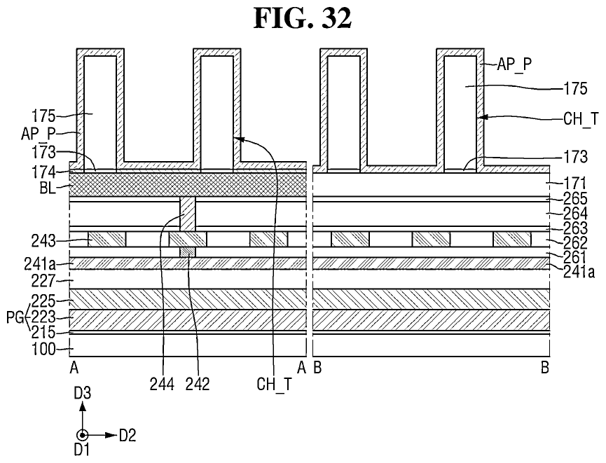

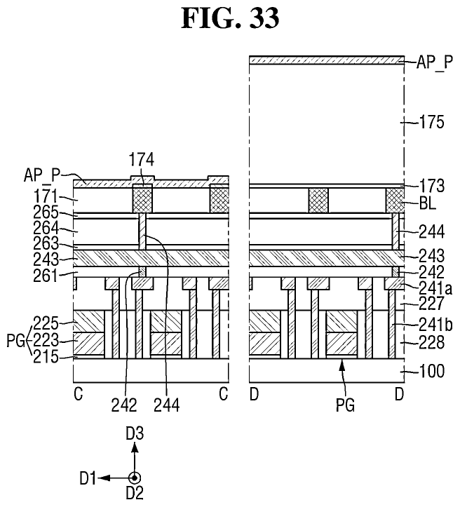

Referring to FIGS. 32 and 33, a pre-channel structure AP_P may be formed along the side walls and bottom face of the channel trench CH_T. The pre-channel structure AP_P may be formed on the liner film 174. The pre-channel structure AP_P may be formed along side walls and upper surface of the protruding insulating pattern 175. The liner film 174 may be disposed between the pre-channel structure AP_P and the upper surface BL_US of the bit line BL.

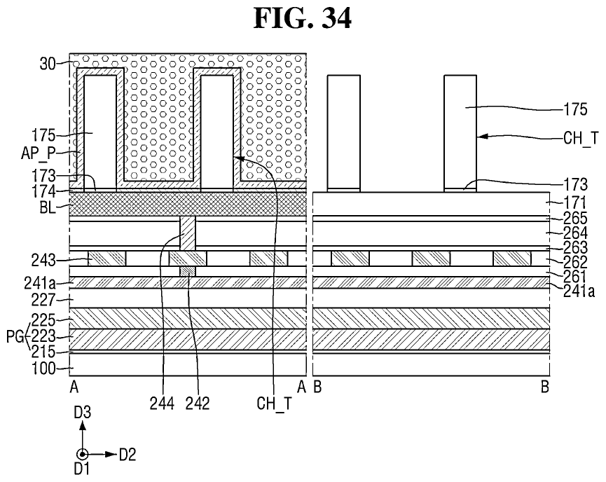

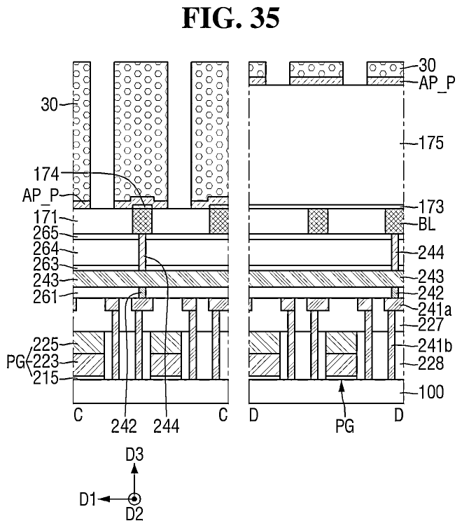

Referring to FIGS. 34 and 35, the sacrificial film 30 may be formed on the pre-channel structure AP_P.

The sacrificial film 30 may be formed on the pre-channel structure AP_P. The sacrificial film 30 may fill the channel trench CH_T. The sacrificial film 30 may be, but not limited to, one of insulating materials and a silicon oxide film formed, using a SOG (Spin On Glass) technique.

A mask pattern (not shown) may then be formed on the sacrificial film 30 and the pre-channel structure AP_P. The sacrificial film 30 and the pre-channel structure AP_P may be etched, using the mask pattern as an etch mask. The pre-channel structure AP_P and the sacrificial film 30 may be removed from the cell lower insulating film 171. As a result, the sacrificial film 30 and the pre-channel structure AP_P may each be spaced apart from each other in the first direction D1.

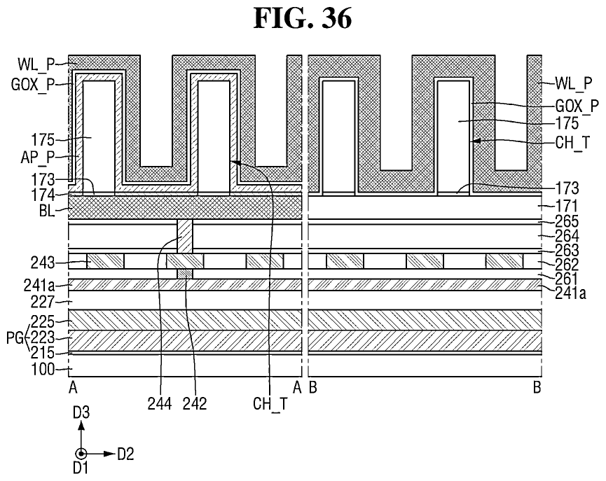

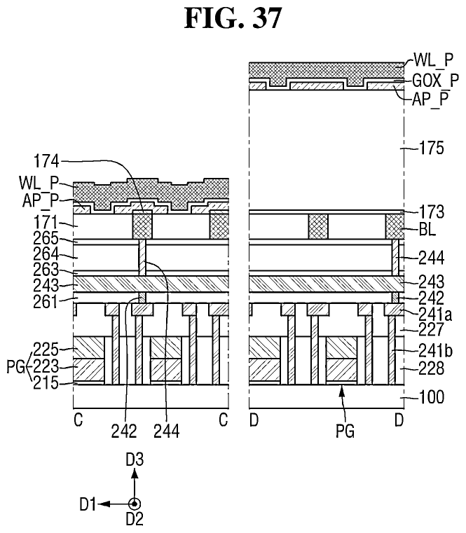

Referring to FIGS. 36 and 37, the sacrificial film 30 is removed, and a pre-gate insulating film GOX_P and a pre-word line WL_P may be formed.

For example, the sacrificial film 30 is removed, and the pre-channel structure AP_P, a part of the cell lower insulating film 171 and a part of the protruding insulating pattern 175 may be exposed. Subsequently, the pre-gate insulating film GOX_P and the pre-word line WL_P may be sequentially formed on the pre-channel structure AP_P, the cell lower insulating film 171 and the protruding insulating pattern 175.

The pre-gate dielectric GOX_P may be formed, but not limited to, using at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) techniques.

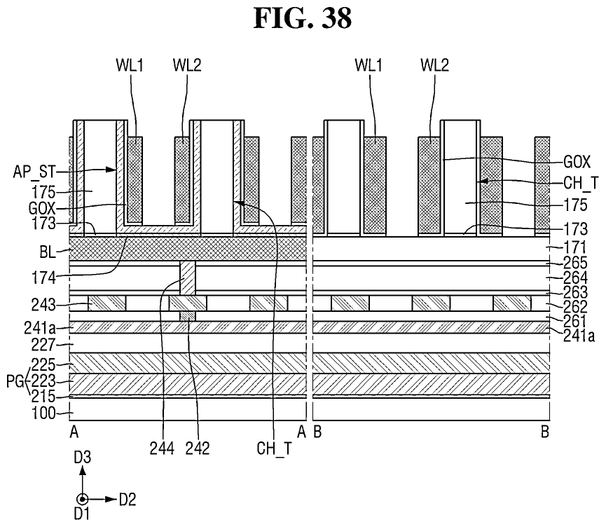

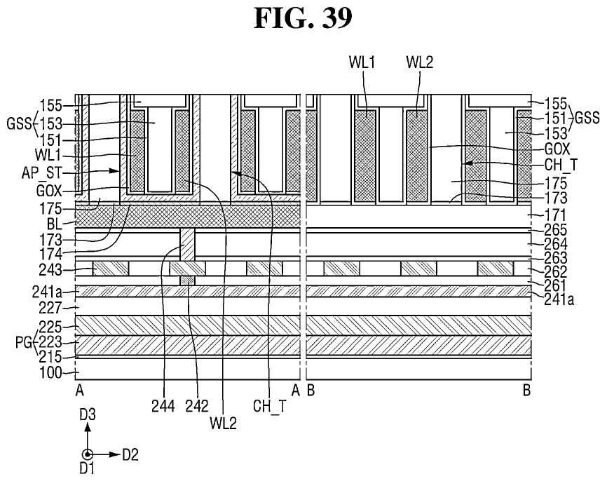

Referring to FIGS. 38 and 39, a channel structure AP_ST, a first word line WL1 and a second word line WL2 may be formed.

For example, an anisotropic etching process may be performed on the pre-word line WL_P. At the time of the anisotropic etching process on the pre-word line WL_P, the pre-word line WL_P is removed, and the first word line WL1 and the second word line WL2 may be formed on the upper surface of the protruding insulating pattern 175. Also, the pre-gate insulating film GOX_P and the pre-channel structure AP_P are removed, and the gate insulating film GOX and the channel structure AP_ST may each be formed on the upper surface of the protruding insulating pattern 175.

In some example embodiments, a part of the gate insulating film GOX may be etched at the time of the anisotropic etching process on the pre-word line WL_P. Therefore, the gate insulating film GOX between the first word line WL1 and the channel structure AP_ST may be separated from the gate insulating film GOX between the second word line WL2 and the channel structure AP_ST.

In some example embodiments, at the time of the anisotropic etching process on the pre-word line WL_P, the channel structure AP_ST between the first word line WL1 and the second word line WL2 may be etched. Therefore, the channel structure AP_ST may be separated into the first channel pattern AP1 and the second channel pattern AP2 of FIG. 14. Also, a part of the upper surface 174_US of the liner film 174 may be exposed.

In some example embodiments, at the time of the anisotropic etching process on the pre-word line WL_P, the channel structure AP_ST and the liner film 174 between the first word line WL1 and the second word line WL2 may be etched. Accordingly, a part of the upper surface BL_US of the bit line BL may be exposed.

Referring to FIG. 39, the gate separation pattern GSS may be formed on the first word line WL1 and the second word line WL2. The gate separation pattern GSS may fill the channel trench CH_T.

For example, the gate separation liner 151 may be formed along the profile of the first word line WL1 and the profile of the second word line WL2. The gate separation liner 151 may also be formed on the upper surface of the protruding insulating pattern 175.

A pre-filling film may be formed on the gate separation liner 151. The pre-filling film may also be formed on the upper surface of the protruding insulating pattern 175. By removing a part of the pre-filling film, the gate separation filling film 153 may be formed on the gate separation liner 151.

A pre-capping film may be formed on the gate separation filling film 153. The pre-capping film may also be formed on the upper surface of the protruding insulating pattern 175. The gate separation capping film 155 may be formed by removing a part of the pre-capping film. While forming the gate separation capping film 155, the gate separation liner 151 and the pre-capping film formed on the upper surface of the protruding insulating pattern 175 may be removed.

Referring to FIGS. 2 and 3, by removing a part of the channel structure AP_ST, the uppermost face of the channel structure AP_ST may become lower than the upper surface of the protruding insulating pattern 175. Subsequently, a pre-landing pad film may be formed on the protruding insulating pattern 175, the gate separation pattern GSS and the channel structure AP_ST. By patterning the pre-landing pad film, the landing pads LP may be formed on the channel structure AP_ST.

A data storage pattern DSP may then be formed on the landing pad LP. The data storage pattern DSP may be connected to the channel structure AP_ST, and may be formed on the gate separation pattern GSS.

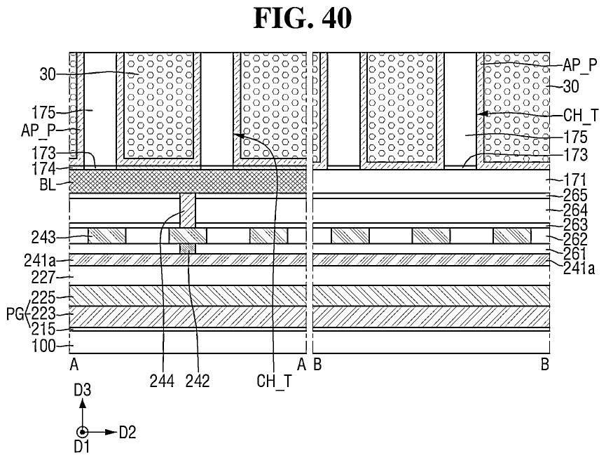

FIGS. 40 to 45 are diagrams for explaining a method for fabricating a semiconductor memory device according to some example embodiments. For convenience of explanation, the points different from those explained in FIGS. 25 to 39 will be mainly explained. For reference, FIG. 40 is a diagram for explaining the fabricating method that proceeds after FIG. 32.

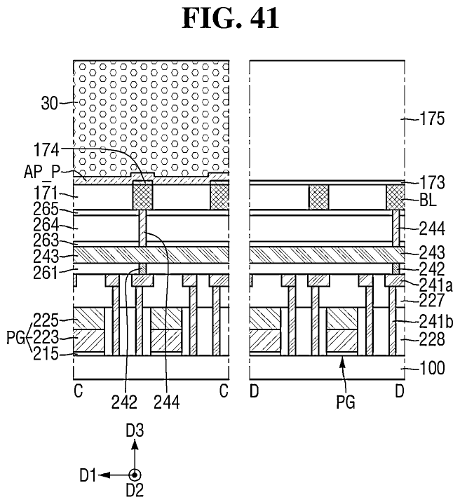

Referring to FIGS. 40 and 41, the pre-channel structure AP_P may be formed along the side walls and bottom face of the channel trench CH_T. The pre-channel structure AP_P may be formed on the liner film 174. The pre-channel structure AP_P is not formed on the upper surface of the protruding insulating pattern 175.

The sacrificial film 30 may then be formed on the pre-channel structure AP_P. The sacrificial film 30 may fill the channel trench CH_T. The sacrificial film 30 may be, but not limited to, one of insulating materials and a silicon oxide film formed using the SOG technique.

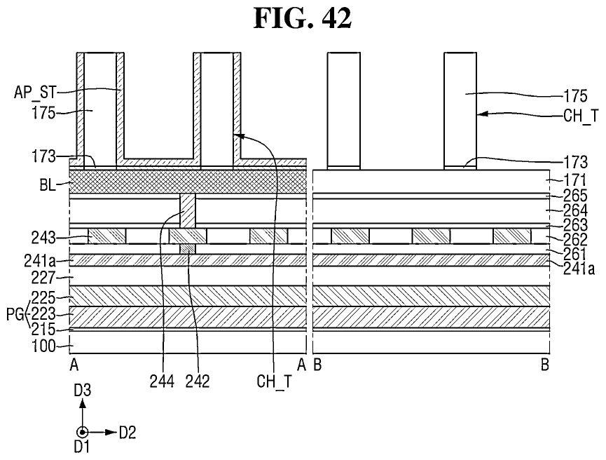

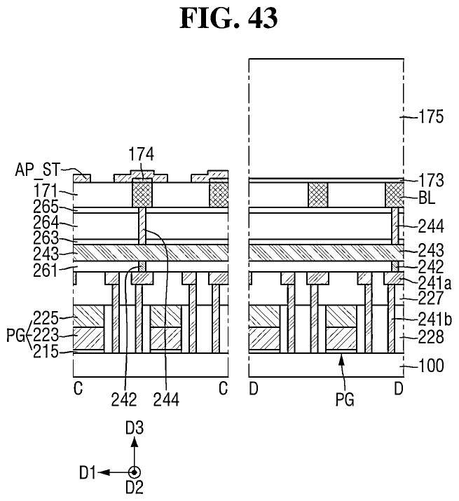

Referring to FIGS. 42 and 43, by patterning the pre-channel structure AP_P, a channel structure AP_ST extending along the side walls and bottom face of the channel trench CH_T may be formed.

For example, a channel separation mask (not shown) may be formed on the sacrificial film 30 and the protruding insulating pattern 175. A part of the sacrificial film 30 may be removed, using the channel separation mask. By removing a part of the sacrificial film 30, a part of the pre-channel structure AP_P may be exposed.

A part of the exposed pre-channel structure AP_P may be removed, using the etching process. Therefore, the channel structure AP_ST may be formed in the channel trench CH_T. The sacrificial film 30 may then be removed inside the channel trench CH_T.

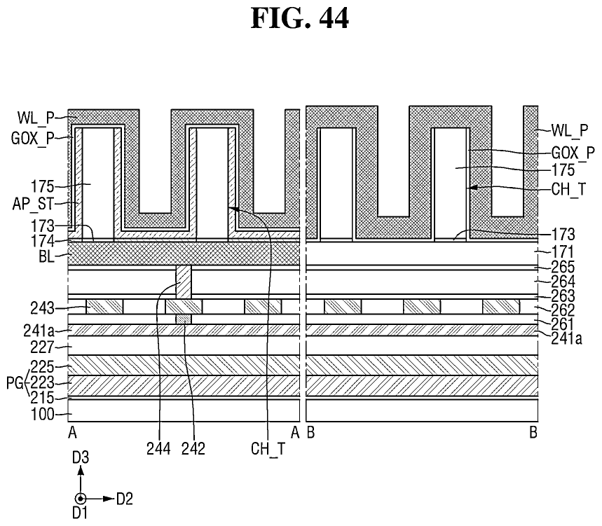

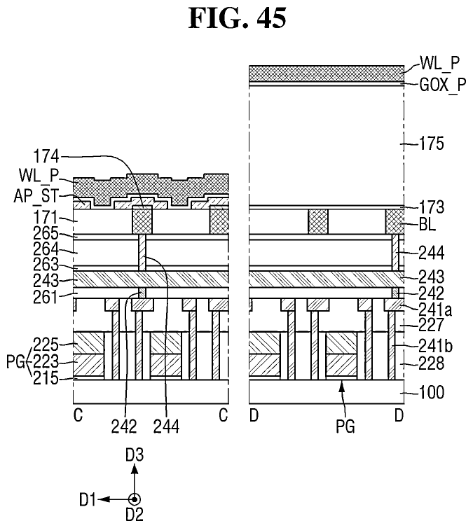

Referring to FIGS. 44 and 45, the pre-gate insulating film GOX_P and the pre-word line WL_P may each be formed on the channel structure AP_ST and the protruding insulating pattern 175.

For example, the pre-gate insulating film GOX_P may be formed on the upper surfaces of the channel structure AP_ST and the protruding insulating pattern 175. Subsequently, a pre-word line WL_P may be formed along the profile of the pre-gate insulating film GOX_P.

Subsequently, an anisotropic etching process is performed on the pre-word line WL_P, and the first word line WL1, the second word line WL2, and the gate insulating film GOX of FIG. 38 may be formed. Subsequent fabricating methods are the same as those described in FIGS. 38 and 39.

In concluding the detailed description, those skilled in the art will appreciate that many variations and modifications may be made to the example embodiments without substantially departing from the principles of the present inventive concept. Therefore, the disclosed example embodiments of the inventive concepts are used in a generic and descriptive sense only and not for purposes of limitation.

What is claimed is:

1. A semiconductor memory device comprising:
a bit line including a metal and extending in a first direction on a substrate;
a channel structure on the bit line, the channel structure including a first channel pattern extending in a second direction, and the channel structure including a second channel pattern spaced apart from the first channel pattern in the first direction and extending in the second direction;
a liner film between the bit line and the channel structure, and the liner film including the metal;
a first word line between the first channel pattern and the second channel pattern, and the first word line extending in the second direction;
a second word line between the first channel pattern and the second channel pattern, the second word line extending in the second direction, and the second word line spaced apart from the first word line in the first direction; and
a first capacitor and a second capacitor respectively on the first channel pattern and the second channel pattern, and connected to the first channel pattern and the second channel pattern.

2. The semiconductor memory device of claim 1,
wherein the liner film extends along an upper surface of the bit line.

3. The semiconductor memory device of claim 1, further comprising:
a protruding insulating pattern on the bit line,
wherein the protruding insulating pattern and the liner film completely cover an upper surface of the bit line.

4. The semiconductor memory device of claim 1,
wherein the liner film includes a nitride.

5. The semiconductor memory device of claim 1, further comprising:
a protruding insulating pattern on the bit line,
wherein the bit line includes a first portion that overlapping the protruding insulating pattern in a third direction, and
the liner film is not disposed on the first portion of the bit line.

6. The semiconductor memory device of claim 1, further comprising:
a protruding insulating pattern on the bit line,
wherein the first channel pattern includes a vertical part extending along side walls of the protruding insulating pattern, and a horizontal part extending along an upper surface of the liner film.

7. The semiconductor memory device of claim 1, further comprising:
a gate separation pattern on the bit line, and separating the first word line and the second word line,
wherein the gate separation pattern contacts the liner film.

8. The semiconductor memory device of claim 1, further comprising:
a gate separation pattern on the bit line, and separating the first word line and the second word line,
wherein the gate separation pattern contacts the bit line.

9. The semiconductor memory device of claim 1, further comprising:
a gate separation pattern on the bit line, and separating the first word line and the second word line; and
a connecting channel pattern connecting the first channel pattern and the second channel pattern,
wherein the connecting channel pattern is between the gate separation pattern and the liner film.

10. The semiconductor memory device of claim 1,
wherein the channel structure includes indium gallium zinc oxide.

11. The semiconductor memory device of claim 1, further comprising:
a shielding structure extending in the first direction, and spaced apart from the bit line in the second direction.

12. The semiconductor memory device of claim 1,
wherein the first channel pattern includes a first metal oxide pattern and a second metal oxide pattern sequentially on the liner film,
the first metal oxide pattern and the second metal oxide pattern each include an amorphous metal oxide, and
a composition of the first metal oxide pattern is different from a composition of the second metal oxide pattern.

13. A semiconductor memory device comprising:
a bit line extending on a substrate in a first direction;
a protruding insulating pattern on the substrate, the protruding insulating pattern including a channel trench exposing the bit line and the protruding insulating pattern extending in a second direction intersecting the first direction;
a liner film on an upper surface of the exposed bit line;
a channel structure extending along a lower surface and side surface of the channel trench, and the channel structure including a first channel pattern and a second channel pattern spaced apart from the first channel pattern in the first direction;
a first word line and a second word line on the channel structure, and the first word line and the second word line spaced apart from each other in the first direction and each extending in the second direction;
a gate insulating film between the first channel pattern and the first word line, and the gate insulating film between the second channel pattern and the second word line; and
a first capacitor and a second capacitor respectively on the first channel pattern and the second channel pattern, and the first capacitor and the second capacitor connected to the first channel pattern and the second channel pattern.

14. The semiconductor memory device of claim 13,
wherein the bit line includes a first element, and
the liner film includes the first element, and a second element different from the first element.

15. The semiconductor memory device of claim 14,
wherein the second element includes nitrogen (N).

16. The semiconductor memory device of claim 13,
wherein the channel structure includes indium gallium zinc oxide.

17. The semiconductor memory device of claim 13,
wherein the channel structure includes a connecting channel pattern connecting the first channel pattern and the second channel pattern, and
the liner film is between the connecting channel pattern and the bit line.

18. The semiconductor memory device of claim 13, further comprising:
a gate separation pattern on the bit line, and separating the first word line and the second word line,
wherein the gate separation pattern contacts the bit line.

19. The semiconductor memory device of claim 13, further comprising:
a gate separation pattern on the bit line, and separating the first word line and the second word line,
wherein the gate separation pattern overlaps the liner film in a third direction.

20. A semiconductor memory device comprising:
a peri-gate structure on a substrate;
a bit line on the peri-gate structure, and extending in a first direction;
a protruding insulating pattern on the substrate, the protruding insulating pattern including a channel trench exposing the bit line and the protruding insulating pattern extending in a second direction intersecting the first direction;
a channel structure in the channel trench, and the channel structure including a horizontal part, and a first vertical part and a second vertical part protruding from the horizontal part;
a liner film between the bit line and the horizontal part of the channel structure, and the liner film including a nitride;
a first word line on the channel structure, and the first word line extending in the second direction;
a second word line on the channel structure, the second word line extending in the second direction, and the second word line spaced apart from the first word line in the first direction;
a gate insulating film between the first vertical part of the channel structure and the first word line, and between the second vertical part of the channel structure and the second word line;
a gate separation pattern on the horizontal part of the channel structure, and the gate separation pattern separating the first word line and the second word line; and
a first capacitor and a second capacitor on the channel structure, and the first capacitor and a second capacitor respectively connected to the first vertical part of the channel structure and the second vertical part of the channel structure.
